(19) United States
(12) Patent Application Publication
(10) Pub. No.: US 2008/0253195 A1
(43) Pub. Date: Oct. 16, 2008

(54) SEMICONDUCTOR MEMORY DEVICE WHICH INCLUDES MOS TRANSISTOR HAVING CHARGE ACCUMULATION LAYER AND CONTROL GATE AND DATA READOUT METHOD THEREOF

(76) Inventor: Yoshihiko Kamata, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/099,514

(22) Filed: Apr. 8, 2008

(30) Foreign Application Priority Data
Apr. 10, 2007 (JP) 2007-103127

(51) Int. Cl. G11C 16/06; G11C 7/00

(52) U.S. Cl. 365/185.21; 365/185.18; 365/207

(57) ABSTRACT

A semiconductor memory device includes first and second memory cells and a sense amplifier. The first memory cell includes a MOS transistor and is capable of retaining n-bit (n is a natural number more than one) first data. The MOS transistor includes a charge accumulation layer and a control gate. The second memory cell retains second data. The second data is a criterion for the first data. The sense amplifier determines the first data read out from the first memory cell and amplifies the first data using a first reference level and a second reference level. The first reference level is obtained based on the second data read out from the second memory cell. The second reference level is generated inside based on the first reference level.

### CROSS-REFERENCE TO RELATED APPLICATIONS

This application is based upon and claims the benefit of priority from prior Japanese Patent Application No. 2007-103127, filed Apr. 10, 2007, the entire contents of which are incorporated herein by reference.

### BACKGROUND OF THE INVENTION

1. Field of the Invention

The present invention relates to a semiconductor memory device and a data readout method thereof. For example, the invention relates to a semiconductor memory device which includes a MOS transistor having a charge accumulation layer and a control gate.

2. Description of the Related Art

Conventionally, a flash memory is well known as a nonvolatile semiconductor memory which can electrically rewrite data. Recently, there is also well known a flash memory (hereinafter sometimes referred to as multi-level flash memory) in which each memory cell can retain at least two-bit data.

As to the data readout method of the multi-level flash memory, there are mainly known three methods, i.e., a word line voltage fluctuation method, a reference line fluctuation method, and an amplifier multiplex method. For example, Jpn. Pat. Appln. KOKAI Publication No. H10-289589 discloses the data readout method.

However, in the conventional data readout method, it is difficult to achieve a balance between improvement of a readout speed and reduction of a chip size.

### BRIEF SUMMARY OF THE INVENTION

A semiconductor memory device according to an aspect of the present invention includes:

a first memory cell which includes a MOS transistor and is capable of retaining n-bit (n is a natural number more than one) first data, the MOS transistor including a charge accumulation layer and a control gate;

a second memory cell which retains second data, the second data being a criterion for the first data; and

a sense amplifier which determines the first data read out from the first memory cell and amplifies the first data using a first reference level and a second reference level, the first reference level being obtained based on the second data read out from the second memory cell, the second reference level being generated based on the first reference level.

A method for reading out data of a semiconductor memory device according to an aspect of the present invention includes:

reading out n-bit (n is a natural number more than one) first data onto a first data line from a first memory cell;

reading out second data onto a second data line from a second memory cell, the second data being a criterion for the first data;

determining a first reference level based on the second data with a sense amplifier;

determining whether one of the n bits of the first data is “0” or “1” based on the first reference level;

determining a second reference level different from first reference level according to determination result based on the first reference level with the sense amplifier; and

determining whether one of the bits except for the bit determined based on the first reference level is “0” or “1” based on the second reference level.

### BRIEF DESCRIPTION OF THE SEVERAL VIEWS OF THE DRAWING

FIG. 1 is a block diagram showing a NOR type flash memory according to a first embodiment of the invention;

FIG. 2 is a circuit diagram showing a memory cell array and a column gate, which are included in the NOR type flash memory according to the first embodiment of the invention;

FIG. 3 is a circuit diagram showing a read circuit included in the NOR type flash memory according to the first embodiment of the invention;

FIGS. 4 and 5 are graphs showing threshold distributions of a memory cell and a reference cell, which are included in the NOR type flash memory according to the first embodiment of the invention;

FIG. 6 is a graph showing currents passed through the memory cell and reference cell in the NOR type flash memory according to the first embodiment of the invention;

FIG. 7 is a graph showing changes in potentials at a data line and a reference data line in the NOR type flash memory according to the first embodiment of the invention;

FIG. 8 is a flowchart showing a readout operation of the NOR type flash memory according to the first embodiment of the invention;

FIG. 9 is a timing chart of various signals during readout of the NOR type flash memory according to the first embodiment of the invention;

FIGS. 10 to 13 are circuit diagrams showing read circuits included in the NOR type flash memory according to the first embodiment of the invention;

FIG. 14 is a timing chart of various signals during readout of the NOR type flash memory according to the first embodiment of the invention;

FIG. 15 is a circuit diagram showing a read circuit included in the NOR type flash memory according to the first embodiment of the invention;

FIG. 16 is a circuit diagram showing a read circuit included in a NOR type flash memory according to a second embodiment of the invention;

FIG. 17 is a diagram showing a control method performed by a control unit included in the NOR type flash memory according to the second embodiment of the invention;

FIG. 18 is a flowchart showing a readout operation of the NOR type flash memory according to the second embodiment of the invention;

FIG. 19 is a circuit diagram showing a read circuit included in a NOR type flash memory according to a third embodiment of the invention;

FIG. 20 is a diagram showing a control method performed by a control unit included in the NOR type flash memory according to the third embodiment of the invention;

FIG. 21 is a circuit diagram showing a read circuit included in a NOR type flash memory according to a fourth embodiment of the invention;

FIGS. 22 and 23 are diagrams showing a control method performed by a control unit included in the NOR type flash memory according to the fourth embodiment of the invention;

FIG. 24 is a circuit diagram showing a read circuit included in a NOR type flash memory according to a fifth embodiment of the invention;

FIG. 25 is a circuit diagram showing a read circuit included in a NOR type flash memory according to a sixth embodiment of the invention;

FIG. 26 is a circuit diagram showing a read circuit included in a NOR type flash memory according to a seventh embodiment of the invention;

FIG. 27 is a flowchart showing a readout operation of the NOR type flash memory according to the seventh embodiment of the invention;

FIG. 28 is a timing chart of various signals during readout of the NOR type flash memory according to the seventh embodiment of the invention;

FIGS. 29 to 32 are circuit diagrams showing a read circuit included in the NOR type flash memory according to the seventh embodiment of the invention;

FIG. 33 is a circuit diagram showing a read circuit included in a NOR type flash memory according to an eighth embodiment of the invention;

FIG. 34 is a diagram showing a threshold distribution of a reference cell included in a NOR type flash memory according to a ninth embodiment of the invention;

FIG. 35 is a circuit diagram showing a differential amplifying unit included in the NOR type flash memory according to the ninth embodiment of the invention;

FIG. 36 is a diagram showing a control method performed by a control unit included in the NOR type flash memory according to the ninth embodiment of the invention;

FIG. 37 is a circuit diagram showing the differential amplifying unit included in the NOR type flash memory according to the ninth embodiment of the invention; and

FIG. 38 is a graph showing a threshold distribution of a memory cell included in a NOR type flash memory according to a modification of the first to ninth embodiments of the invention.

### DETAILED DESCRIPTION OF THE INVENTION

In the following description, a state in which charges are accumulated in a charge accumulation layer is defined as “written state (“0” data)” and a state in which the charges have come out of the charge accumulation layer is defined as “erased state (“1” data)”.

### First Embodiment

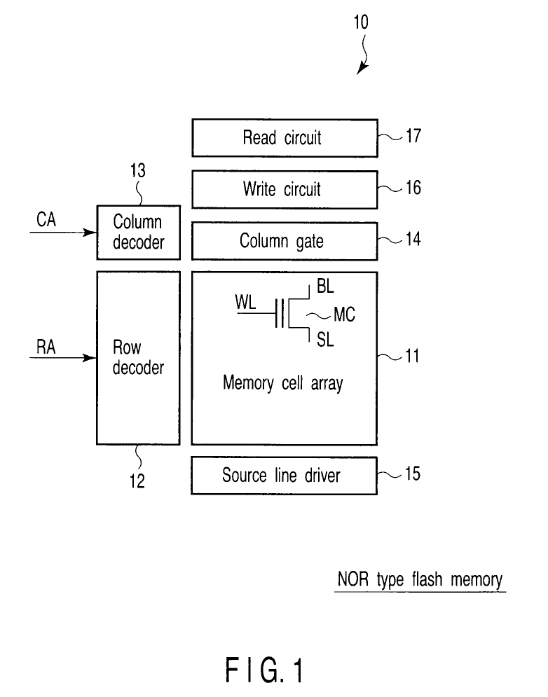

A semiconductor memory device according to a first embodiment of the invention will be described below with reference to FIG. 1. FIG. 1 is a block diagram showing a NOR type flash memory according to the first embodiment of the invention.

As shown in FIG. 1, a flash memory 10 includes a memory cell array 11, a row decoder 12, a column decoder 13, a column gate 14, a source line driver 15, a write circuit 16, and a read circuit 17.

The memory cell array 11 includes plural NOR type flash memory cells (hereinafter simply referred to as memory cell MC) arranged in a matrix. Each memory cell MC is connected to a bit line BL, a word line WL, and a source line SL. The row decoder 12 selects a row direction, i.e., the word line WL of the memory cell array 11. The column decoder 13 selects a column direction of the memory cell array 11. The column gate 14 selects the bit line BL to connect the bit line BL to a data line based on a selection operation of the column decoder 13. The source line driver 15 applies a voltage to the source line SL. The write circuit 16 applies the voltage to the data line according to write data. The read circuit 17 senses data read out on the data line to amplify the data.

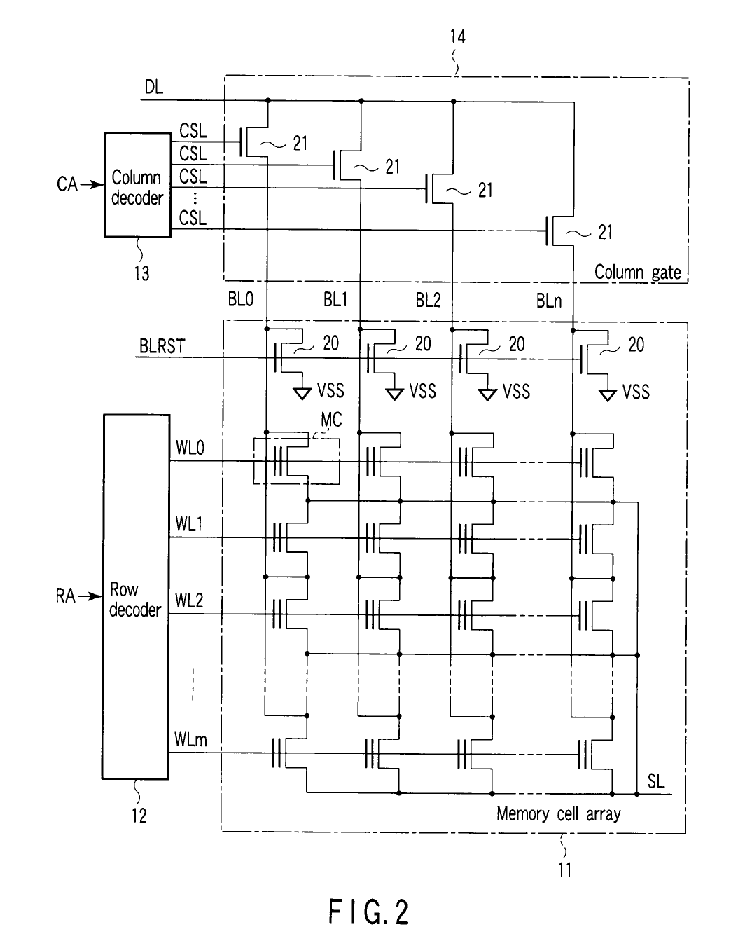

Configurations of the memory cell array 11 and column gate 14 will be described below with reference to FIG. 2. FIG. 2 is a circuit diagram showing the memory cell array 11 and column gate 14.

First, the memory cell array 11 will be described. As shown in FIG. 2, the memory cell array 11 includes ((m+1)×(n+1)) (m and n are natural numbers) memory cells MC. The memory cell MC is a MOS transistor including a stacked gate which has both a charge accumulation layer (for example, floating gate) and a control gate. The charge accumulation layer is formed on a semiconductor substrate with a gate insulating film interposed therebetween. For example, the charge accumulation layer is made of polycrystalline silicon. The control gate is formed on the charge accumulation layer with an inter-gate insulating film interposed therebetween. For example, the control gate is made of a material such as polycrystalline silicon, a metal, and a multi-layer film thereof. Control gates of the memory cells MC existing on the same row are commonly connected to one of the same word lines WL0 to WLm. Drains of the memory cells MC existing on the same column are commonly connected to one of the same bit lines BL0 to BLn. Sources of memory cells MC are commonly connected to the same source line SL. In the following description, for the purpose of convenience, sometimes the word lines WL0 to WLm and the bit lines BL0 to BLn are collectively referred to as word line WL and bit line BL, respectively.

The memory cell array 11 includes a reset transistor 20 provided in each bit line BL. The reset transistor 20 is an n-channel MOS transistor in which the drain is connected to each bit line BL while a voltage VSS (for example, 0V) is applied to the source. A control circuit (not shown) gives a signal BLRST to the gate of the reset transistor 20. The reset transistor 20 is provided to reset a potential at the bit line BL to 0V, and the signal BLRST is set to an “H” level during the reset.

The column gate 14 will be described next. As shown in FIG. 2, the column gate 14 includes an n-channel MOS transistor 21 provided in each of the bit lines BL0 to BLn. One end of a current path of the MOS transistor 21 is connected to each of the bit lines BL0 to BLn, and the other end of the current path is commonly connected to the data line DL. The gate of the n-channel MOS transistor 21 is connected to a column selection line CSL. In writing or reading the data, the column decoder 13 selects one of the column selection lines CSL to connect one of the bit lines BL to the data line DL. Although only one data line DL is shown in FIG. 2, obviously plural data lines DL may be provided.

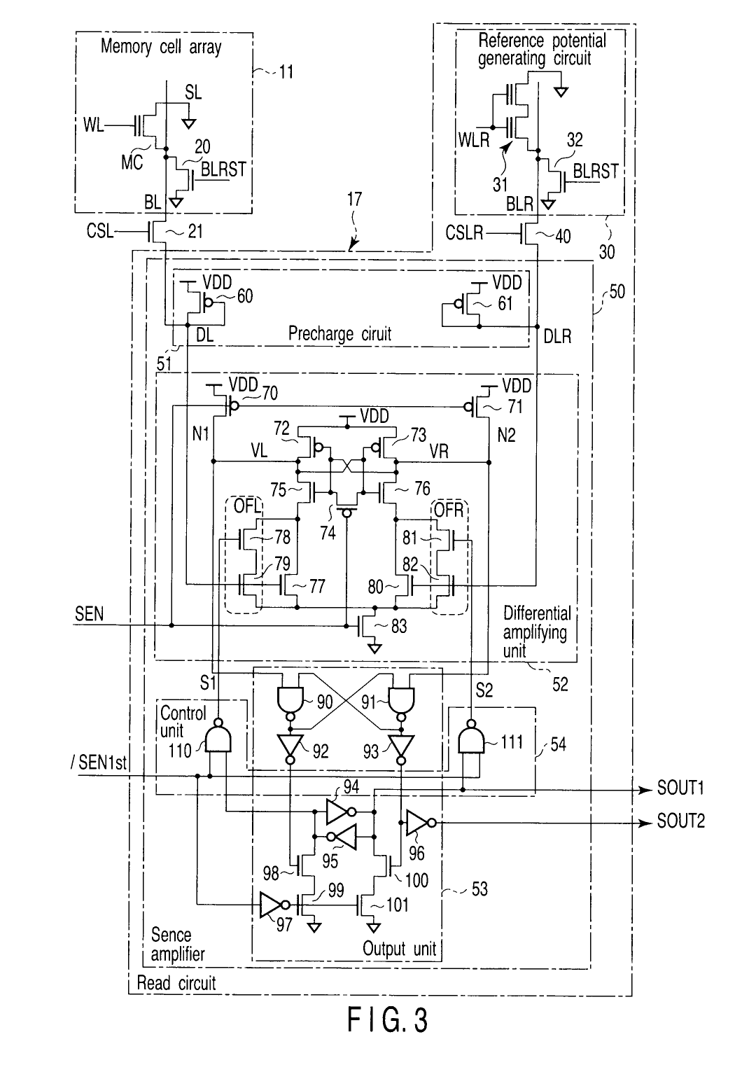

The read circuit 17 will be described below with reference to FIG. 3. As shown in FIG. 3, the read circuit 17 includes a reference potential generating circuit 30, an n-channel MOS transistor 40, and a sense amplifier 50.

The reference potential generating circuit 30 includes a reference cell 31 and a reset transistor 32. The reference cell 31 retains reference data which becomes a standard in making a determination of the data read out from the memory cell MC, in reading the data. The reference cell 31 includes two MOS transistors connected in series, which have the same structure as the memory cell MC. The voltage VSS is given to the source of the reference cell 31, the drain of the reference cell 31 is connected to a reference bit line BLR, and the gate of the reference cell 31 is connected to a reference word line WLR. In reading the data, the reference word line WLR is selected at the same timing as the word line WL. The reset transistor 32 is an n-channel MOS transistor in which the drain is connected to the reference bit line BLR while the voltage VSS is applied to the source. The signal BLRST is given to the gate of the reset transistor 32. The reset transistor 32 is provided to reset the potential at the reference bit line BLR to 0V.

The MOS transistor 40 connects the reference bit line BLR to a reference data line DLR. That is, one end of the current path of the MOS transistor 40 is connected to the reference bit line BLR and the other end is connected to the reference data line DLR. A column selection line CSLR is connected to the gate of the MOS transistor 40. The column selection line CSLR is selected in reading the data, whereby the reference data read out from the reference cell 31 is transferred to the reference data line DLR.

The sense amplifier 50 mainly includes a precharge circuit 51, a differential amplifying unit 52, an output unit 53, and a control unit 54.

The precharge circuit 51 includes p-channel MOS transistors 60 and 61. The source of the MOS transistor 60 is connected to a power-supply potential VDD, and the gate and drain thereof are connected to the data line DL. The source of the MOS transistor 61 is connected to the power-supply potential VDD, and the gate and drain thereof are connected to the reference data line DLR. The MOS transistors 60 and 61 are provided to precharge the bit line BL (and data line DL) and reference bit line BLR (and reference data line DLR) in reading the data respectively.

The differential amplifying unit 52 determines and amplifies the data read out from the memory cell MC onto the data line DL using a reference level which is obtained based on reference data read out from the reference cell 31 onto the reference data line DLR. The output unit 53 outputs the data determined and amplified by the differential amplifying unit 52 to outside. The control unit 54 controls the reference level in the differential amplifying unit 52 by generating signals S1 and S2.

Configurations of the differential amplifying unit 52, output unit 53, and control unit 54 will be described below. First, the differential amplifying unit 52 will be described.

As shown in FIG. 3, the differential amplifying unit 52 includes p-channel MOS transistors 70 to 74 and n-channel MOS transistors 75 to 83. The sources of the MOS transistors 70 and 71 are connected to a voltage VDD, a sense amplifier enable signal SEN given from the control circuit (not shown) is input to the gates of the MOS transistors 70 and 71, and the drains of the MOS transistors 70 and 71 are connected to nodes N1 and N2, respectively. Hereinafter, potentials at nodes N1 and N2 are referred to as VL and VR, respectively.

In the MOS transistor 72, the source is connected to the voltage VDD, the drain is connected to the node N1, and the gate is connected to the drain of the MOS transistor 73. In the MOS transistor 73, the source is connected to the voltage VDD, the drain is connected to the node N2, and the gate is connected to the drain of the MOS transistor 72. In the MOS transistor 75, the drain is connected to the drain of the MOS transistor 72, i.e., to the gate of the MOS transistor 73, and the gate is connected to the gate of the MOS transistor 72, i.e., to the drain of the MOS transistor 73. In the MOS transistor 76, the drain is connected to the drain of the MOS transistor 73, i.e., to the gate of the MOS transistor 72, and the gate is connected to the gate of the MOS transistor 73, i.e., to the drain of the MOS transistor 72. In the MOS transistor 74, a signal SEN is input to the gate, one of the source and drain is connected to the gate of the MOS transistor 75, and the other is connected to the gate of the MOS transistor 76.

In the MOS transistor 77, the gate is connected to the data line DL and the drain is connected to the source of the MOS transistor 75. In the MOS transistor 78, the signal S1 is input to the gate and the drain is connected to the source of the MOS transistor 75. In the MOS transistor 79, the gate is connected to the data line DL and the drain is connected to the source of the MOS transistor 78. In the MOS transistor 80, the gate is connected to the reference data line DLR and the drain is connected to the source of the MOS transistor 76. In the MOS transistor 81, the signal S2 is input to the gate and the drain is connected to the source of the MOS transistor 76. In the MOS transistor 82, the gate is connected to the reference data line DLR and the drain is connected to the source of the MOS transistor 81. In the MOS transistor 83, the signal SEN is input to the gate, the drain is connected to the sources of the MOS transistors 77, 79, 80, and 82, and the source is connected to the voltage VSS.

That is, the differential amplifying unit 52 of the first embodiment is a latch type differential amplifier in which the data read out from the memory cell MC is input to first gates (gates of MOS transistors 77 and 79) while the reference data read out from the reference cell 31 is input to second gates (gates of MOS transistors 80 and 82). The number of current paths controlled by the potential at the first gate and the number of current paths controlled by the potential at the second gate are controlled by the signals S1 and S2. That is, the current path formed by the MOS transistors 78 and 79 and the current path formed by the MOS transistors 81 and 82 act as an offset current path for the current path formed by the MOS transistors 77 and 80, respectively. In FIG. 3, the point shown by a broken line with the symbol “OFL” indicates the offset on the memory cell, and the point shown by a broken line with the symbol “OFR” indicates the offset on the reference cell.

The output unit 53 will be described below. The output unit 53 includes NAND gates 90 and 91, inverters 92 to 97, and n-channel MOS transistors 98 to 101. The NAND gate 90 performs a NAND operation of the potential (VL) at the node N1 and the output from the NAND gate 91. The NAND gate 91 performs a NAND operation of the potential (VR) at the node N2 and the output from the NAND gate 90. The inverters 92 and 93 invert the outputs from the NAND gates 90 and 91 respectively. The inverter 96 inverts the output from the inverter 93, and outputs the inversion result as a signal SOUT2.

The inverter 97 inverts a signal /SEN1st given from the control circuit (not shown). The signal /SEN1st is set to an “L” level in a first sense operation while the signal /SEN1st is set to an “H” level in a second sense operation. The first sense operation and the second sense operation will be described later.

In the MOS transistors 98 and 100, the gates are connected to output nodes of the inverters 92 and 93, respectively, and the sources are connected to the drains of MOS transistors 99 and 101, respectively. In the MOS transistors 99 and 101, the gates are connected to the output node of the inverter 97 and the sources are connected to the voltage VSS. In the inverter 94, an input node is connected to the drain of the MOS transistor 98 and the output node is connected to the drain of the MOS transistor 100. In the inverter 95, the input node is connected to the drain of the MOS transistor 100, i.e., to the output node of the inverter 94, and the output node is connected to the drain of the MOS transistor 98, i.e., to the input node of the inverter 94. Levels at the output node of the inverter 94 and the input node of the inverter 95 are output as a signal SOUT1.

The control unit 54 will next be described. The control unit 54 includes two NAND gates 110 and 111. The NAND gate 110 performs the NAND operation of the signal /SEN1st and a signal at a connection node of the input node of the inverter 94 and the output node of the inverter 95. The operation result of the NAND gate 110 is given as the signal S1 to the differential amplifying unit 52. The NAND gate 111 performs the NAND operation of the signal /SEN1st and a signal (i.e., signal SOUT1) at a connection node of the input node of the inverter 95 and the output node of the inverter 94. The operation result of the NAND gate 111 is given as the signal S2 to the differential amplifying unit 52.

The memory cell MC and the reference cell 31 in the flash memory 10 having the above-described configuration will be described below.

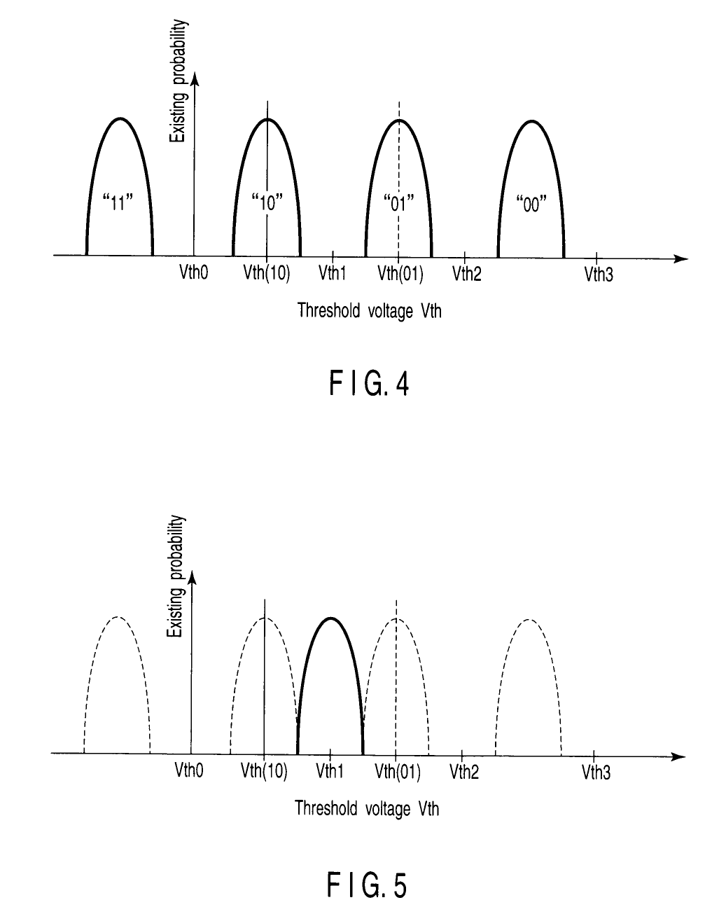

Each of the memory cells MC can retain four levels of data (binary two-bit data). FIG. 4 is a graph showing a threshold distribution of the memory cell. In FIG. 4, a horizontal axis indicates a threshold voltage Vth and a vertical axis indicates an existing probability of the memory cell.

As shown in FIG. 4, the memory cell can retain the four levels of data, i.e., “11”, “10”, “01”, and “00” in the ascending order of the threshold voltage Vth. The threshold voltage Vth at the memory cell MC retaining the “11” data is Vth<Vth0. The threshold voltage Vth at the memory cell MC retaining the “10” data is Vth0<Vth<Vth1. The threshold voltage Vth at the memory cell MC retaining the “01” data is Vth1<Vth<Vth2. The threshold voltage Vth at the memory cell MC retaining the “00” data is Vth2<Vth<Vth3. Hereinafter, a voltage which becomes a median of the threshold distribution of the memory cell MC retaining the “10” data is referred to as Vth(10) and a voltage which becomes a median of the threshold distribution of the memory cell MC retaining the “01” data is referred to as Vth(01).

FIG. 5 is a graph showing a threshold distribution of the reference cell 31. In FIG. 5, the horizontal axis indicates the threshold voltage Vth and the vertical axis indicates the existing probability of the memory cell.

As shown in FIG. 5, the threshold voltage Vth at the reference cell 31 is set to Vth(10)<Vth<Vth(01). Preferably the threshold voltage Vth at the reference cell 31 is higher than the maximum value of the threshold distribution of the memory cell MC retaining the “10” data and lower than the minimum value of the threshold distribution of the memory cell MC retaining the “01” data.

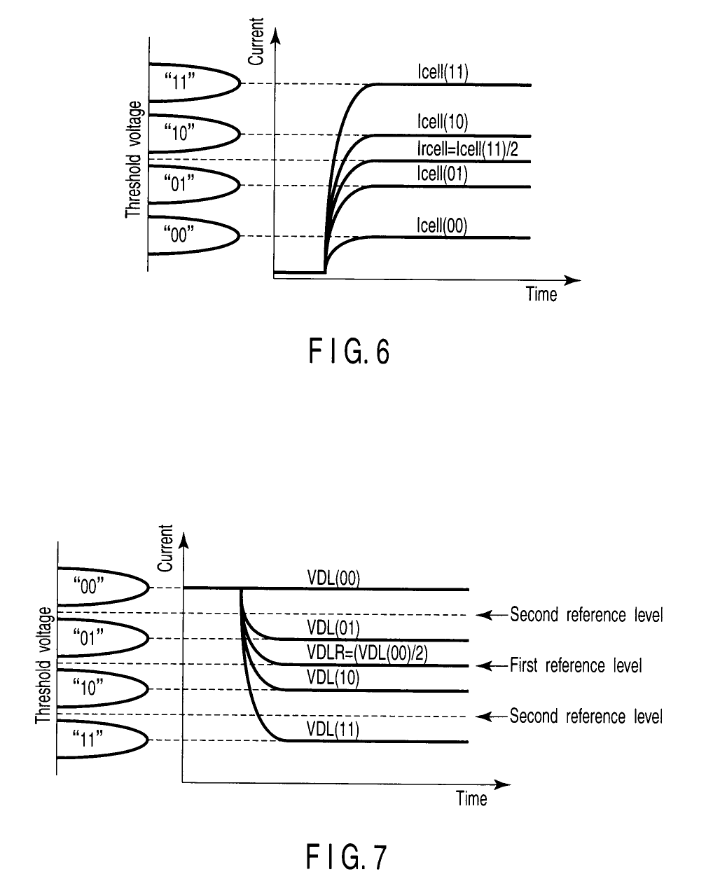

FIG. 6 is a graph showing currents passed through the bit line BL in reading out the four levels of data onto the bit line BL from the memory cell MC and a current passed through the reference bit line BLR in reading out the reference data onto the reference bit line BLR from the reference cell 31. In FIG. 6, the vertical axis indicates current and the horizontal axis indicates time. The currents are indicated while correlated with the four levels of data retained by the memory cell MC.

As shown in FIG. 6, assuming that Icell(00), Icell(01), Icell(10), and Icell(11) are the currents passed through the bit line BL in reading out the “00” data, “01” data, “10” data, and “11” data, respectively, Icell(00)<Icell(01)<Icell(10)<Icell(11) holds. The current passed through the reference bit line BLR in reading out the reference data is Ircell=Icell(11)/2. However, Icell(00) to Icell(11) and Ircell have predetermined distributions similar to the threshold voltage Vth. Accordingly, it is necessary that Ircell exist between a median of the distribution of Icell(01) and a median of the distribution of Icell(10). Preferably, Ircell is larger than the maximum value of the distribution of Icell(01) and lower than the minimum value of the distribution of Icell(10).

When the two-bit data is read out from the memory cell MC, a higher-order bit and a lower bit of the two-bit data are output as the signals SOUT1 and SOUT2, respectively, from the sense amplifier 50.

FIG. 7 is a graph showing voltages generated in the data line DL in reading out the four levels of data onto the bit line BL from the memory cell MC and a voltage generated in the reference data line DLR in reading out the reference data onto the reference bit line BLR from the reference cell 31. In FIG. 7, the vertical axis indicates voltage and the horizontal axis indicates time. The voltages are indicated while correlated with the four levels of data retained by the memory cell MC.

As shown in FIG. 7, assuming that VDL(00), VDL(01), VDL(10), and VDL(11) are the voltages generated at the data line DL in reading out the “00” data, “01” data, “10” data, and “11” data, respectively, VDL(00)>VDL(01)>VDL(10)>VDL(11) holds. The voltage generated at the reference data line DLR in reading out the reference data is VDLR=VDL(00)/2. However, VDL(00) to VDL(11) and VDLR have predetermined distributions similar to the threshold voltage Vth. Accordingly, it is necessary that VDLR exists between a median of the distribution of VDL(01) and a median of the distribution of VDL(10). Preferably, VDLR is larger than the maximum value of the distribution of VDL(10) and lower than the minimum value of the distribution of VDL(01).

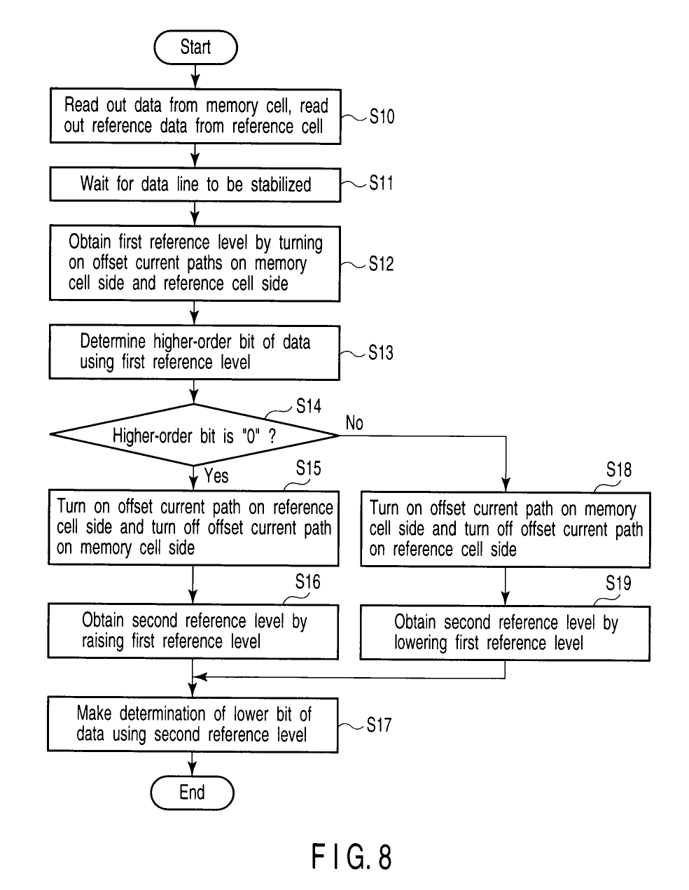

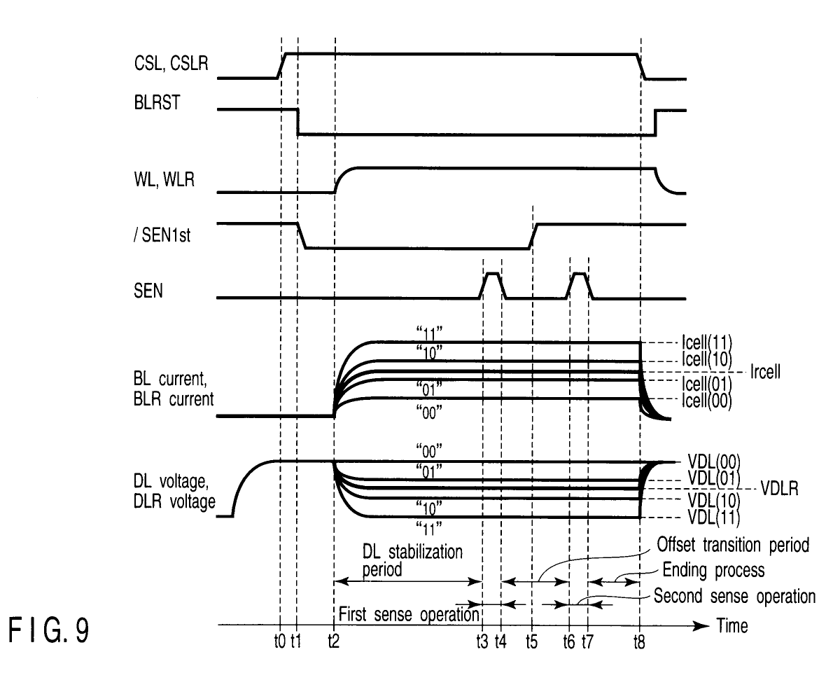

Focusing particularly on an operation performed by the read circuit 17, a data readout method in the flash memory 10 according to the first embodiment will be described below with reference to FIGS. 3, 8, and 9. FIG. 8 is a flowchart showing the data readout operation performed by the read circuit 17, and FIG. 9 is a timing chart of changes in potentials at the column selection lines CSL and CSLR, signal BLRST, word lines WL and WLR, signal /SEN1st, and the signal SEN, changes in currents of the bit line BL and reference bit line BLR, and changes in potentials at the data line DL and reference data line DLR.

In reading out the data, first, the MOS transistors 60 and 61 precharge the data line DL and reference data line DLR at precharge potentials. The voltage VDL(00) is equal to the precharge potential. At a time t0, the “H” level is given to the column selection lines CSL and CSLR, and the bit line BL and reference bit line BLR are connected to the data line DL and reference data line DLR, respectively. At a time t1, the signal BLRST is set to the “L” level and the reset transistors 20 and 32 are turned off. The signal /SEN1st is set to the “L” level.

The data is read out from the memory cell MC to the bit line BL, and the reference data is read out from the reference cell 31 to the reference bit line BLR (time t2 in Step S10 of FIG. 8). That is, the row decoder 12 gives the “H” level to the word lines WL and WLR. As a result, the one of the currents Icell(00) to Icell(11) is passed through the bit line BL according to the data retained by the selected memory cell MC, and the potential at the data line DL becomes one of the voltages VDL(00) to VDL(11). The current Ircell is passed through the reference bit line BLR, whereby the potential at the reference data line DLR becomes the voltage VDLR.

Then, the read circuit 17 waits for the potential to be stabilized at the data line DL (time t2 to t3, Step S11). After a period for stabilizing the data line DL elapses, the control circuit sets the signal /SEN1st to the “L” level to perform the first sense operation. The first sense operation shall mean an operation which determines the difference between “0” and “1” in the higher-order bit of the data read out from the memory cell MC. In the first sense operation, because the signal /SEN1st is set to the “L” level, the signals S1 and S2 are set to the “H” level. Therefore, the offset current path (formed by the MOS transistors 78 and 79) on the side of the memory cell MC is turned on, and the offset current path (formed by MOS transistors 81 and 82) on the side of the reference cell 31 is turned on. This enables the differential amplifying unit 52 to obtain a first reference level (Step S12). The differential amplifying unit 52 determines the higher-order bit of the data based on the first reference level (time t3 to t4, Step S13). That is, as described above with reference to FIG. 7, the differential amplifying unit 52 determines that the higher-order bit is the “0” data when the potential at the data line DL is higher than the potential (VDLR) between the voltages VDL(01) and VDL(10), and the differential amplifying unit 52 determines that the higher-order bit is the “1” data when the potential is lower than the potential (VDLR).

When the first sense operation is ended, the control circuit sets the signal /SEN1st to the “H” level (time t5). As a result of Step S13, when the higher-order bit is the “0” data (YES in Step S14), the MOS transistor 81 is turned on and the MOS transistor 78 is turned off in the differential amplifying unit 52. That is, the offset current path on the side of the memory cell MC is turned off, and the offset current path on the side of the reference cell 31 is turned on. This enables the differential amplifying unit 52 to obtain a second reference level, higher than the first reference level (Step S16). The second reference level is a potential located between the voltages VDL(00) and VDL(01) in FIG. 7. The differential amplifying unit 52 determines the lower-order bit of the data based on the second reference level (time t6 to t7, Step S17). A second sense operation shall mean an operation which determines the difference between “0” and “1” in the lower-order bit of the data read out from the memory cell MC.

As a result of Step S14, when the higher-order bit is the “1” data (NO in Step S14), the MOS transistor 81 is turned off and the MOS transistor 78 is turned on in the differential amplifying unit 52. That is, the offset current path on the side of the memory cell MC is turned on, and the offset current path on the side of the reference cell 31 is turned off (Step S18). This enables the differential amplifying unit 52 to obtain the second reference level, lower than the first reference level (Step S19). The second reference level is a potential located between the voltages VDL(11) and VDL(10) in FIG. 7. The differential amplifying unit 52 determines the lower-order bit of the data based on the second reference level (time t6 to t7 in Step S17).

Then, the column selection lines CSL and CSLR are set to the “L” level, and the data readout operation is ended.

A specific example of the operation performed by the read circuit 17 during the data readout operation will be described below. First, the readout of the “00” data will be described.

(“00” Data Readout)

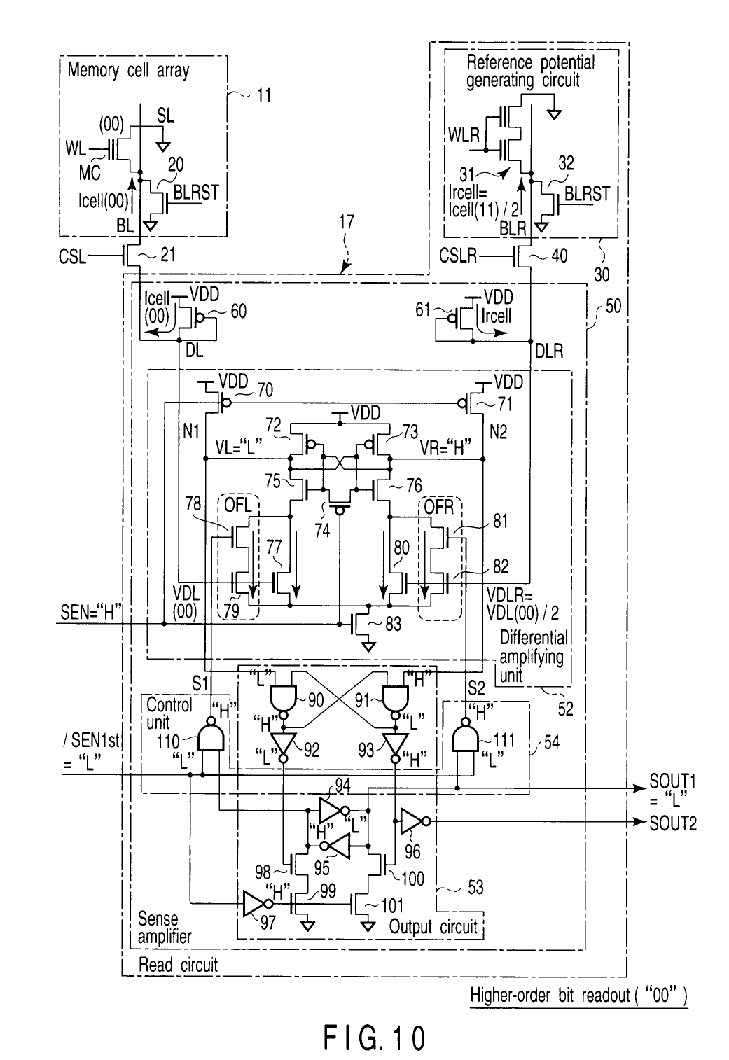

FIG. 10 is a circuit diagram of the read circuit 17, and shows the first sense operation in reading out the “00” data. As shown in FIG. 10, the current Icell(00) is passed through the bit line BL and the potential at the data line DL is the voltage VDL(00). The current Ircell=Icell(11)/2 is passed through the reference bit line BLR and the potential at the reference data line DLR is the voltage VDLR=VDL(00)/2. The signal SEN is set to the “H” level and the signal /SEN1st is set to the “L” level.

Accordingly, because the outputs (signals S1 and S2) of the NAND gates 110 and 111 become the “H” level in the control unit 54, the MOS transistors 78, 79, 81, and 82 are turned on in the differential amplifying unit 52. That is, the differential amplifying unit 52 obtains the first reference level. The first reference level is VDL(11)<VDL(10)<first reference level<VDL(01)<VDL(00). Because of VDL(00)>>VDLR, i.e., VDL(00)>first reference level, the potential VL at the node N1 becomes the “L” level and the potential VR at the node N2 becomes the “H” level.

Therefore, in the output unit 53, the outputs of the NAND gates 90 and 91 become the “H” level and “L” level, respectively. Then, the MOS transistor 100 is turned on, and the potentials at the input node of the inverter 95 and the output node of the inverter 94 become the “L” level. Accordingly, the signal SOUT1 becomes the “L” level to output the higher-order bit of “0”.

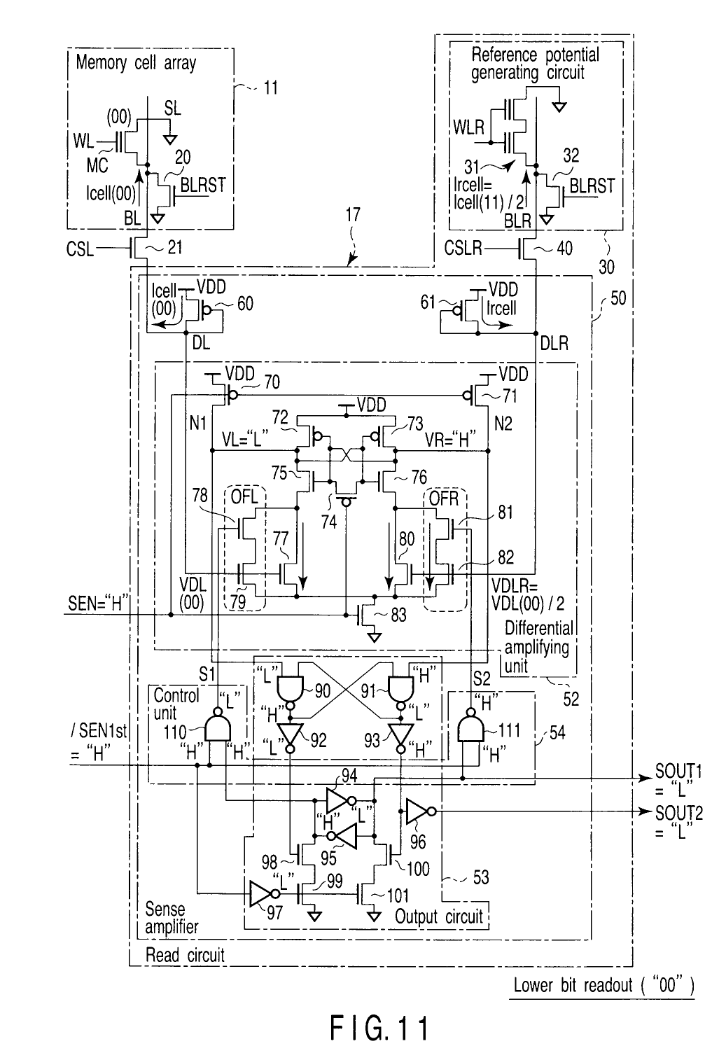

Then, the second sense operation is performed to make the determination of the lower bit. FIG. 11 is a circuit diagram of the read circuit 17, and shows the second sense operation in reading out the “00” data. As shown in FIG. 11, in performing the second sense operation, the signal /SEN1st is set to the “H” level. The input node and output node of the inverter 94 are set to the “H” level and “L” level.

Therefore, in the control unit 54, the outputs of the NAND gates 110 and 111 become the “L” level and “H” level, respectively. Therefore, in the differential amplifying unit 52, the MOS transistor 81 is turned on and the MOS transistor 78 is turned off. This enables the differential amplifying unit 52 to obtain the second reference level, higher than the first reference level. The second reference level is VDL(11)<VDL(10)<VDL(01)<second reference level<VDL(00). Because of VDL(00)>>VDLR and VDL(00)>second reference level, the current passed through the MOS transistor 77 is higher than the sum of the current passed through the MOS transistor 80 and the current passed through the MOS transistors 81 and 82. Therefore, the potentials VL and VR are still in the “L” level and “H” level, respectively.

Accordingly, because the outputs of the NAND gates 90 and 91 are still in the “H” level and “L” level, respectively, in the output unit 53, the signal SOUT2 becomes the “L” level to read out the lower bit of “0”. Because the signal /SEN1st becomes the “H” level during the second sense operation, the MOS transistors 99 and 101 are turned off. Accordingly, also in the second sense operation, the inverters 94 and 95 retain the higher-order bit data latched during the first sense operation.

The determination of the difference between the higher-order bit of “0” and lower bit of “0” is made by the above-described operation.

(“01” Data Readout)

Next, the readout of the “01” data will be described. The first sense operation in reading out the “01” data is omitted because it is the same as that in reading out the “00” data. However, the current Icell(01) is passed through the bit line BL, the potential at the data line DL becomes the voltage VDL(01), and VDL(01)>VDLR holds.

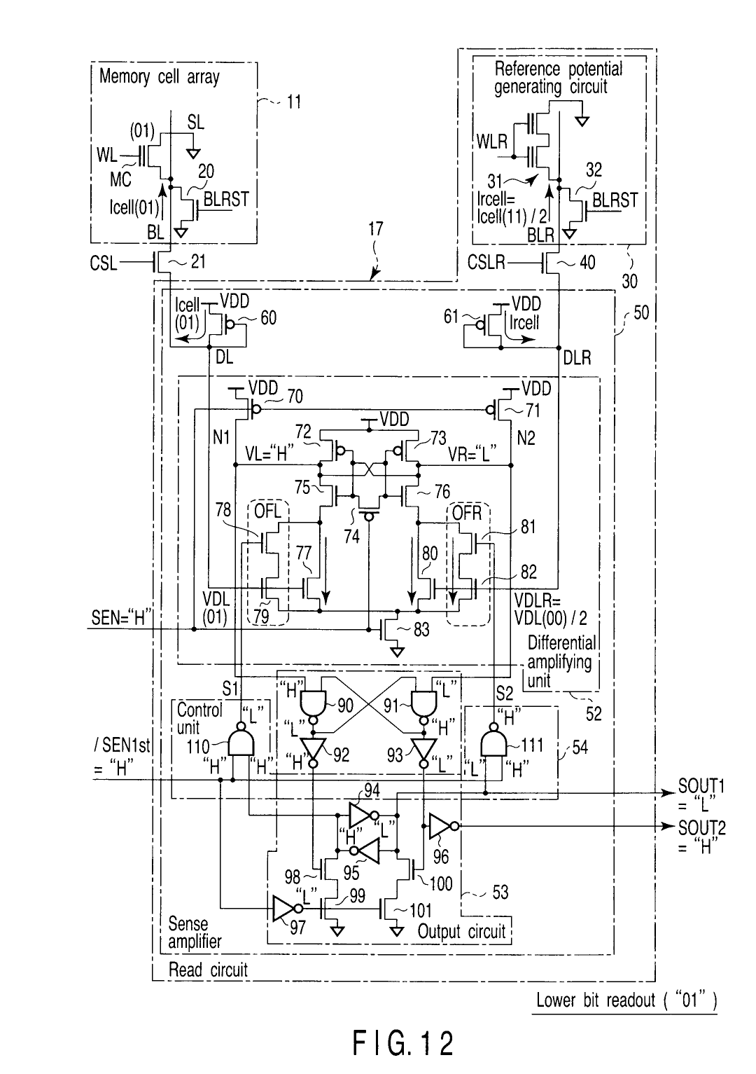

FIG. 12 is a circuit diagram of the read circuit 17, and shows the second sense operation in reading out the “01” data.

Similarly to the case of FIG. 10, because the outputs of the NAND gates 110 and 111 become the “L” level and “H” level, respectively, the MOS transistor 81 is turned on while the MOS transistor 78 is turned off in the differential amplifying unit 52. That is, the differential amplifying unit 52 obtains the second reference level, higher than the first reference level. The second reference level is VDL(11)<VDL(10)<VDL(01)<second reference level<VDL(00). Because of VDL(01)>VDRL and VDL(01)<second reference level, inversely to the case of FIG. 10, the current passed through the MOS transistor 77 is smaller than the sum of the current passed through the MOS transistor 80 and the current passed through the MOS transistors 81 and 82. Therefore, the potentials VL and VR are changed to the “H” level and “L” level, respectively.

Accordingly, because the outputs of the NAND gates 90 and 91 in the output unit 53 are changed to the “L” level and “H” level, respectively, the signal SOUT2 becomes the “H” level to read out the lower bit of “1”.

The determination of the difference between the higher-order bit of “0” and lower bit of “1” is made by the above-described operation.

(“10” Data Readout)

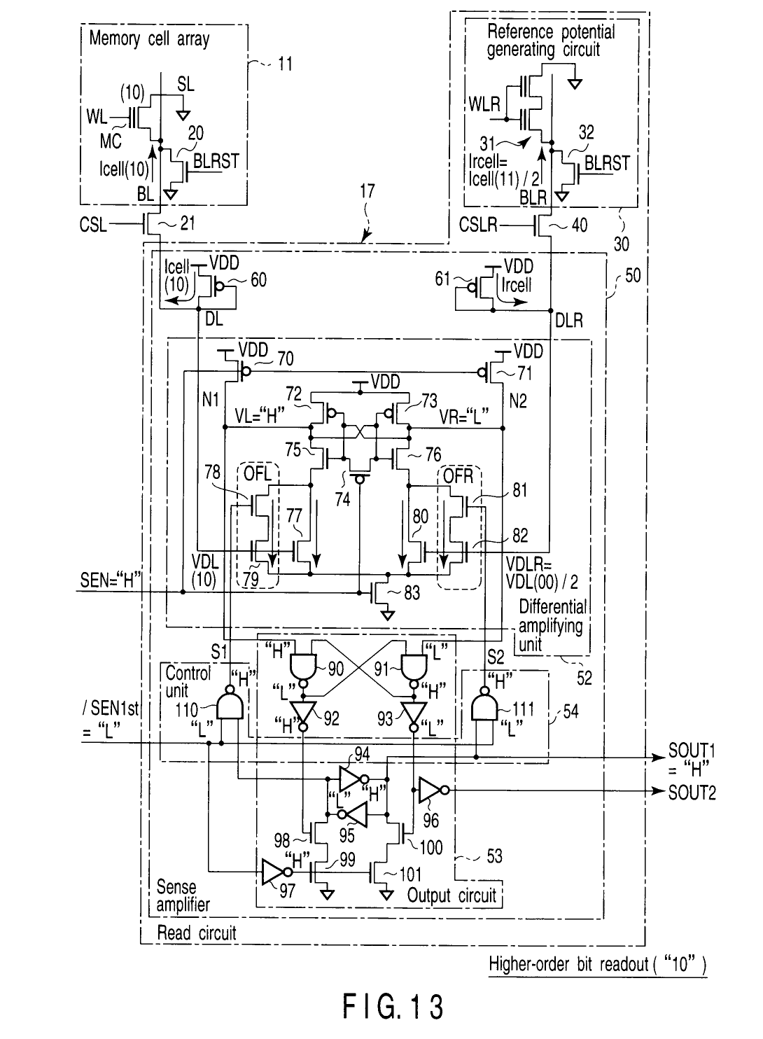

FIG. 13 is a circuit diagram of the read circuit 17, and shows the first sense operation in reading out the “10” data. As shown in FIG. 13, the current Icell(10) is passed through the bit line BL and the potential at the data line DL becomes the voltage VDL(10).

During the first sense operation, similarly to the case of FIG. 10, because the outputs (signals S1 and S2) of the NAND gates 110 and 111 become the “H” level, the MOS transistors 78 and 81 are turned on in the differential amplifying unit 52. That is, the differential amplifying unit 52 obtains the first reference level. The first reference level is VDL(11)<VDL(10)<first reference level<VDL(01)<VDL(00). Because of VDL(10)<VDLR, i.e., VDL(10)<first reference level, the potential VL becomes the “H” level and the potential VR becomes the “L” level.

Because the outputs of the NAND gates 90 and 91 become the “L” level and “H” level, respectively, in the output unit 53, the MOS transistor 98 is turned on, and the potentials at the output node of the inverter 95 and the input node of the inverter 94 become the “L” level. Accordingly, the signal SOUT1 becomes the “H” level to output the higher-order bit of “1”.

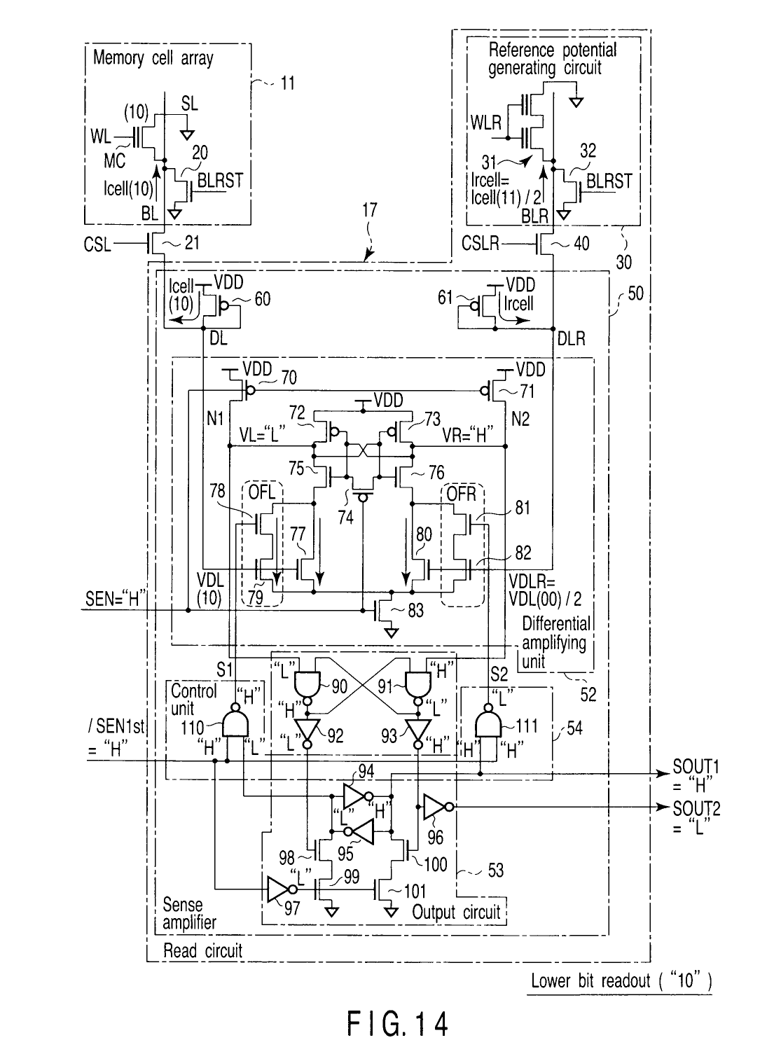

Then, the second sense operation is performed to make the determination of the lower bit. FIG. 14 is a circuit diagram of the read circuit 17, and shows the second sense operation in reading out the “10” data. As shown in FIG. 14, in performing the second sense operation, the signal /SEN1st is set to the “H” level. The input node and output node of the inverter 94 are set to the “L” level and “H” level, respectively.

Therefore, in the control unit 54, the outputs of the NAND gates 110 and 111 become the “H” level and “L” level, respectively. Therefore, in the differential amplifying unit 52, the MOS transistor 78 is turned on and the MOS transistor 81 is turned off. This enables the differential amplifying unit 52 to obtain the second reference level, lower than the first reference level. The second reference level is VDL(11)<second reference level<VDL(10)<VDL(01)<VDL(00). Because of VDL(10)<VDLR and VDL(10)>second reference level, the current passed through the MOS transistor 80 is lower than the sum of the current passed through the MOS transistor 77 and the current passed through the MOS transistors 78 and 79. Therefore, the potentials VL and VR are still in the “L” level and “H” level, respectively.

Accordingly, because the outputs of the NAND gates 90 and 91 are changed to the “H” level and “L” level, respectively, in the output unit 53, the signal SOUT2 becomes the “L” level to read out the lower bit of “0”.

The determination of the difference between the higher-order bit of “1” and lower bit of “0” is made by the above-described operation.

(“11” Data Readout)

Next, the readout of the “11” data will be described. The first sense operation in reading out the “11” data is omitted because it is the same as that in reading out the “10” data. However, the current Icell(11) is passed through the bit line BL, the potential at the data line DL becomes the voltage VDL(11), and VDL(11)>>VDLR holds.

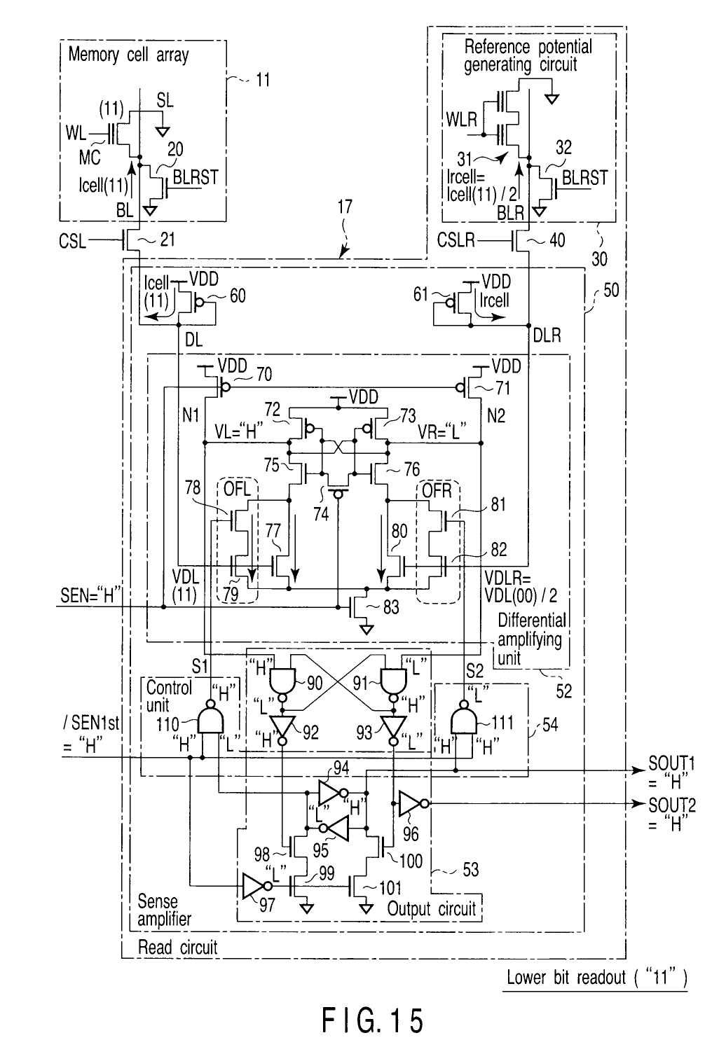

FIG. 15 is a circuit diagram of the read circuit 17, and shows the second sense operation in reading out the “11” data.

Similarly to the case of FIG. 14, because the outputs of the NAND gates 110 and 111 become the “H” level and “L” level, respectively, the MOS transistor 78 is turned on while the MOS transistor 81 is turned off in the differential amplifying unit 52. That is, the differential amplifying unit 52 obtains the second reference level, lower than the first reference level. The second reference level is VDL(11)<second reference level<VDL(10)<VDL(01)<VDL(00). Because of VDL(11)<<VDLR and VDL(11)<second reference level, inversely to the case of FIG. 14, the current passed through the MOS transistor 80 is larger than the sum of the current passed through the MOS transistor 77 and the current passed through the MOS transistors 78 and 79. Therefore, the potentials VL and VR are changed to the “H” level and “L” level, respectively.

Accordingly, because the outputs of the NAND gates 90 and 91 in the output unit 53 are changed to the “L” level and “H” level, respectively, the signal SOUT2 becomes the “H” level to read out the lower bit of “1”.

The determination of the difference between the higher-order bit of “0” and lower bit of “1” is made by the above-described operation.

An effect (1) described below is obtained in the semiconductor memory device according to the first embodiment.

(1) An operating speed can be enhanced while enlargement of a chip size is suppressed.

In the configuration according to the first embodiment, an operating point of the sense amplifier 50 is changed in making the determination of the lower bit according to the value of the higher-order bit. The change of the operating point is performed by changing the offset amount of the current path in the differential amplifying unit 52 of the sense amplifier 50. Accordingly, the readout speed of the flash memory can be enhanced without enlarging the chip size. The effect will be described below.

As described above, in the data readout method of the multi-level flash memory, there are known the three methods, i.e., the word line voltage fluctuation method, the reference line fluctuation method, and the amplifier multiplex method. In the word line voltage fluctuation method, plural voltages are applied to the word line to check whether or not the memory cell is turned on, thereby making the determination of the data. Accordingly, the configuration of the sense amplifier can be formed like the case in which the memory cell retains one-bit (binary) data, and the sense amplifier can be realized with the small area. However, it is necessary to make a transition of the voltage at the word line, and to wait for the voltage at the bit line to swing sufficiently. Accordingly, because the operating speed is too slow on the order of microseconds, the word line voltage fluctuation method is not suitable for random access.

In the reference line fluctuation method, the plural reference cells are prepared, and the plural kinds of currents passed through the reference data line are changed by a combination of the reference cells. The determination of the data is made by comparing the currents and the current passed through the data line. In the reference line fluctuation method, the relatively high-speed operation can be performed compared with the word line voltage fluctuation method. However, it is necessary to wait for the potential at the data line to be stabilized every time the current passed through the reference data line is changed. For example, in the case of the determination of two-bit data, it is necessary that the current passed through the reference data line be changed three times. Accordingly, the reference line fluctuation method is not suitable from the viewpoint of the operating speed.

In the amplifier multiplex method, the reference data line and the amplifier are prepared to make the determination of each data. In this case, since the waiting for the stabilization of the data line and the sense operation are performed one time, the data readout can be performed at an extremely high speed. However, because the amplifier is multiplexed, the chip size is enlarged. Because the plural reference cells are provided, a long time is required to adjust the reference cells during a test, which results in deterioration of throughput.

However, in the configuration according to the first embodiment, the determination of the data is made by the same sense amplifier (differential amplifying unit 52) 50. To achieve this, the differential amplifying unit 52 makes the determination of the higher-order bit using the first reference level. Then, the differential amplifying unit 52 makes the determination of the lower bit using the second reference level which is higher or lower than the first reference level. The differential amplifying unit 52 generates the second reference level in itself based on the first reference level. More specifically, the offset amount of the current path through which the current is passed according to the potential at the data line DL and the offset amount of the current path through which the current is passed according to the potential at the reference data line DLR are changed.

Accordingly, it is not necessary to vary the potentials or currents of the word line or data line and reference data line, and the waiting time for the word line or data line and reference data line to be stabilized is not required. The time on the order of tens of microseconds is required to vary the word line or data line and reference data line. However, in the first embodiment, the variation of the potentials or currents is not required, and the time on the order of several nanoseconds is required to change the offset amount. Accordingly, the readout of the multi-level flash memory can be performed at the same speed as the case in which the data is read out from the memory cell retaining the one-bit data.

In the configuration of the sense amplifier, the addition of only the offset current path and the control unit 54 is required, and the reference cell has the same configuration as the case in which the memory cell retains one-bit data. Accordingly, the enlargement of the chip size can be suppressed to the minimum level.

### Second Embodiment

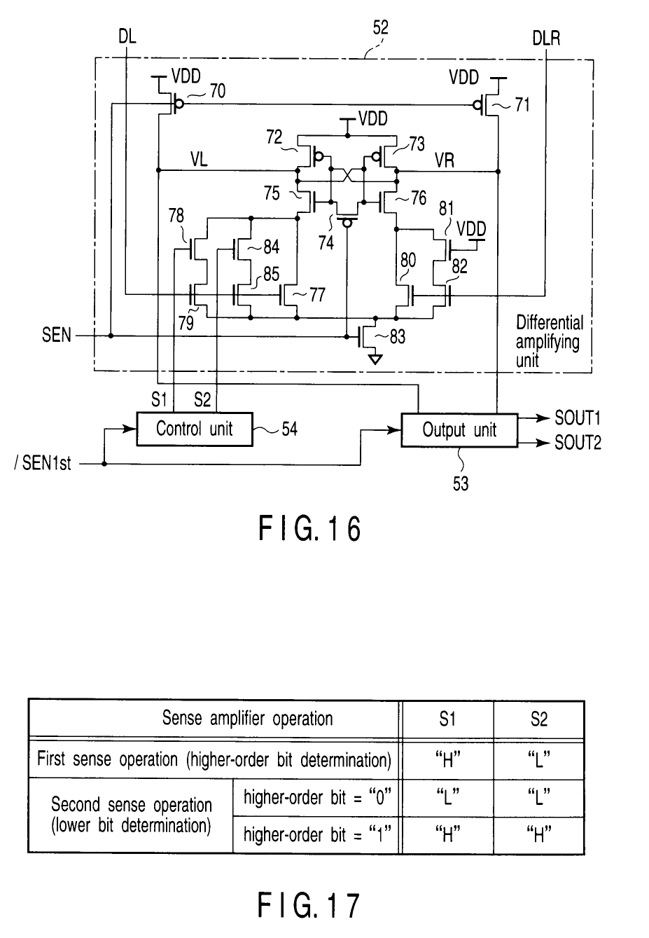

A semiconductor memory device according to a second embodiment of the invention will be described below. In the second embodiment, the current path controlled by the potential at the reference data line DLR in the first embodiment is kept constant, and the offset amount of the current path controlled by the potential at the data line DL in the first embodiment is changed to obtain the second reference level. Because other configurations are similar to those of the first embodiment, only the point that is different from the first embodiment will be described below. FIG. 16 is a circuit diagram partially showing the sense amplifier 50 included in the NOR type flash memory according to the second embodiment.

As shown in FIG. 16, in the differential amplifying unit 52 of the sense amplifier 50, the configuration of FIG. 3 described in the first embodiment is modified as follows. In the differential amplifying unit 52, the gate of the MOS transistor 81 is connected to the voltage VDD. Accordingly, the MOS transistor 81 is always turned on during the first sense operation and second sense operation.

N-channel MOS transistors 84 and 85 are added. In the MOS transistor 84, the drain is connected to the source of the MOS transistor 75, the source is connected to the drain of the MOS transistor 85, and the signal S2 is input to the gate. In the MOS transistor 85, the source is connected to the drain of the MOS transistor 83 and the gate is connected to the data line DL. That is, the current path of the MOS transistors 84 and 85 is added as the offset of the current path through which the current is passed according to the potential at the data line DL.

The control unit 54 generates the signals S1 and S2 as shown in FIG. 17. FIG. 17 is a diagram showing the signals S1 and S2 during the first and second sense operations. As shown in FIG. 17, the control unit 54 sets the signals S1 and S2 to the “H” level and “L” level, respectively, during the first sense operation. During the second sense operation, the control unit 54 sets the signals S1 and S2 to the “L” level when the higher-order bit is the “0” data, and sets the signals S1 and S2 to the “H” level when the lower bit is the “1” data.

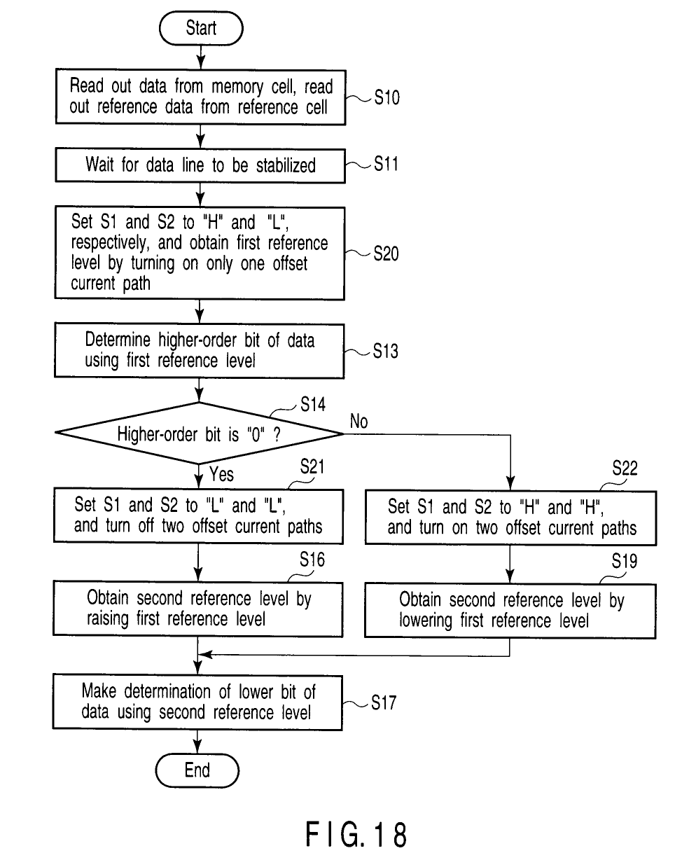

Focusing particularly on the operation in the sense amplifier 50 of the read circuit 17, the data readout method in the flash memory 10 according to the second embodiment will be described below with reference to FIG. 18. FIG. 18 is a flowchart showing the data readout operation of the read circuit 17.

The processes to Step S11 are performed like the first embodiment. Then, the control unit 54 sets the signals S1 and S2 to the “H” level and “L” level, respectively. Therefore, the MOS transistor 78 is turned on and the MOS transistor 84 is turned off. Accordingly, the two current paths (the current path by the MOS transistor 77 and the current path by the MOS transistors 78 and 79) are controlled by the potential at the data line DL, and the two current paths (the current path by the MOS transistor 80 and the current path by the MOS transistors 81 and 82) are controlled by the potential at the reference data line DLR. This enables the first reference level to be obtained (Step S20). As described in the first embodiment, the first reference level is VDL(11)<VDL(10)<first reference level<VDL(01)<VDL(00). The determination of the higher-order bit of the data is made using the first reference level (Step S13).

As a result of Step S13, when the higher-order bit is the “0” data (YES in Step S14), the control unit 54 sets the signals S1 and S2 to the “L” level, thereby turning off the MOS transistors 78 and 84 (Step S21). That is, a ratio of the current path controlled by the potential at the data line DL and the current path controlled by the potential at the reference data line DLR becomes 1:2, thereby obtaining the second reference level (Step S16). The second reference level is obtained by raising the first reference level, and VDL(11)<VDL(10)<VDL(01)<second reference level<VDL(00) holds. The determination of the lower bit of the data is made using the second reference level (Step S17).

As a result of Step S13, when the higher-order bit is the “1” data (NO in Step S14), the control unit 54 sets the signals S1 and S2 to the “H” level, thereby turning on the MOS transistors 78 and 84 (Step S22). That is, a ratio of the current path controlled by the potential at the data line DL and the current path controlled by the potential at the reference data line DLR becomes 3:2, thereby obtaining the second reference level (Step S19). The second reference level is obtained by lowering the first reference level, and VDL(11)<second reference level<VDL(10)<VDL(01)<VDL(00) holds. The determination of the lower bit of the data is made using the second reference level (Step S17).

The same effect as the first embodiment is also obtained in the configuration of the second embodiment.

### Third Embodiment

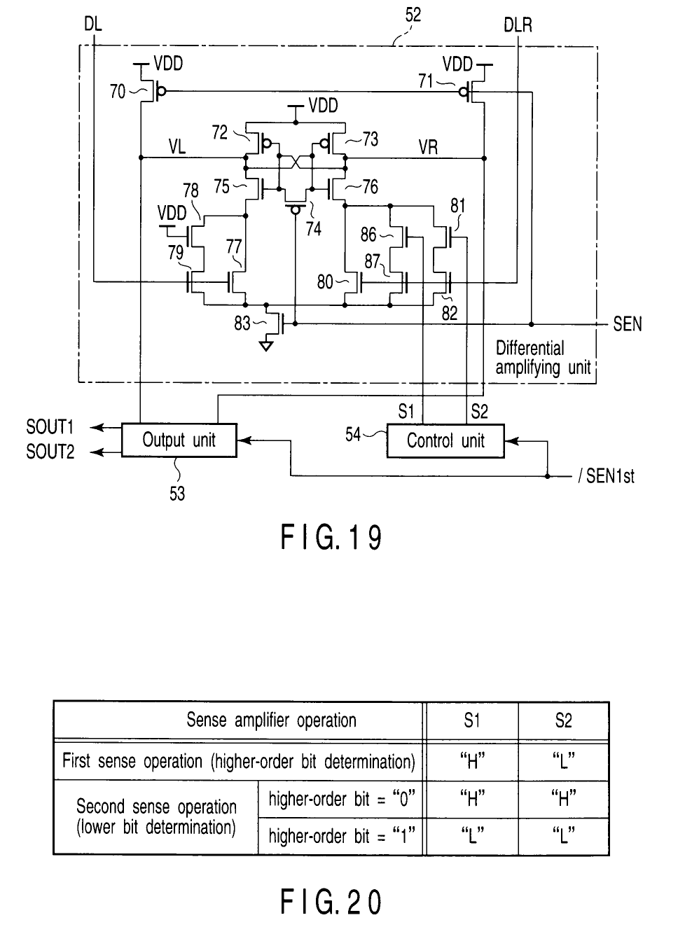

A semiconductor memory device according to a third embodiment of the invention will be described below. In the third embodiment, the current path controlled by the potential at the data line DL in the first embodiment is kept constant, and the offset amount of the current path controlled by the potential at the reference data line DLR in the first embodiment is changed to obtain the second reference level. Because other configurations are similar to those of the first embodiment, only the point that is different from the first embodiment will be described below. FIG. 19 is a circuit diagram partially showing a configuration of the sense amplifier 50 included in the NOR type flash memory of the third embodiment.

As shown in FIG. 19, in the differential amplifying unit 52 of the sense amplifier 50, the configuration of FIG. 3 described in the first embodiment is modified as follows. In the differential amplifying unit 52, the gate of the MOS transistor 78 is connected to the voltage VDD. Accordingly, the MOS transistor 78 is always turned on during the first sense operation and second sense operation.

N-channel MOS transistors 86 and 87 are added. In the MOS transistor 86, the drain is connected to the source of the MOS transistor 76, the source is connected to the drain of the MOS transistor 87, and the signal S1 is input to the gate. In the MOS transistor 87, the source is connected to the drain of the MOS transistor 83 and the gate is connected to the reference data line DLR. That is, the current path of the MOS transistors 86 and 87 is added as the offset of the current path through which the current is passed according to the potential at the reference data line DLR.

The control unit 54 generates the signals S1 and S2 as shown in FIG. 20. FIG. 20 is a diagram showing the signals S1 and S2 during the first and second sense operations. As shown in FIG. 20, the control unit 54 sets the signals S1 and S2 to the “H” level and “L” level, respectively, during the first sense operation. During the second sense operation, the control unit 54 sets the signals S1 and S2 to the “H” level when the higher-order bit is the “0” data, and sets the signals S1 and S2 to the “L” level when the lower bit is the “1” data.

The operation of the sense amplifier 50 during the data readout is substantially similar to that of FIG. 18 in the second embodiment except for the control method in the control unit 54. That is, because the control unit 54 sets the signals S1 and S2 to the “H” level and “L” level, respectively, after Step S11, the MOS transistor 86 is turned on and the MOS transistor 81 is turned off. Accordingly, the two current paths (the current path by the MOS transistor 77 and the current path by the MOS transistors 78 and 79) are controlled by the potential at the data line DL, and the two current paths (the current path by the MOS transistor 80 and the current path by the MOS transistors 86 and 87) are controlled by the potential at the reference data line DLR. This enables the first reference level to be obtained (Step S20). The determination of the higher-order bit of the data is made using the first reference level (Step S13).

As a result of Step S13, when the higher-order bit is the “0” data (YES in Step S14), the control unit 54 sets the signals S1 and S2 to the “H” level, thereby turning on the MOS transistors 81 and 84. That is, the ratio of the current path controlled by the potential at the data line DL and the current path controlled by the potential at the reference data line DLR becomes 2:3, thereby obtaining the second reference level (Step S16). The second reference level is obtained by raising the first reference level, and VDL(11)<VDL(10)<VDL(01)<second reference level<VDL(00) holds. The determination of the lower bit of the data is made using the second reference level (Step S17).

As a result of Step S13, when the higher-order bit is the “1” data (NO in Step S14), the control unit 54 sets the signals S1 and S2 to the “L” level, thereby turning off the MOS transistors 81 and 86. That is, the ratio of the current path controlled by the potential at the data line DL and the current path controlled by the potential at the reference data line DLR becomes 2:1, thereby obtaining the second reference level (Step S19). The second reference level is obtained by lowering the first reference level, and VDL(11)<second reference level<VDL(10)<VDL(01)<VDL(00) holds. The determination of the lower bit of the data is made using the second reference level (Step S17).

The same effect as the first embodiment is also obtained in the third embodiment.

### Fourth Embodiment

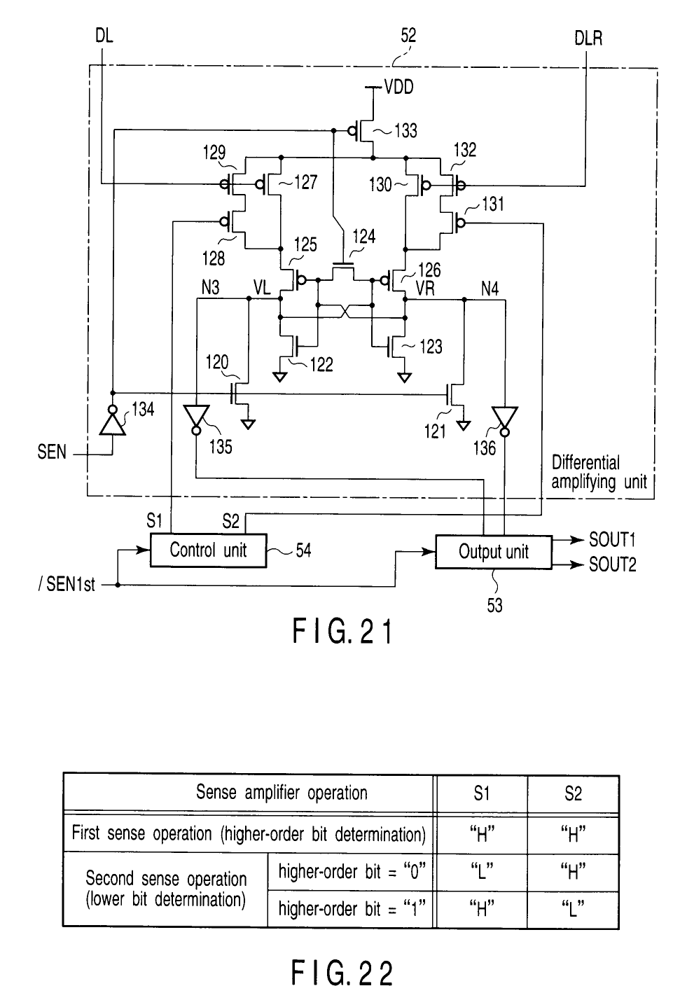

A semiconductor memory device according to a fourth embodiment of the invention will be described below. In the fourth embodiment, the n-channel MOS transistor is replaced with a p-channel MOS transistor in the input of the gate of the differential amplifying unit 52 in the sense amplifier 50 described in the first embodiment. Because other configurations are similar to those of the first embodiment, the description thereof is omitted. FIG. 21 is a circuit diagram showing a part of the sense amplifier 50 included in the NOR type flash memory of the fourth embodiment.

As shown in FIG. 21, the differential amplifying unit 52 of the sense amplifier 50 includes n-channel MOS transistors 120 to 124, p-channel MOS transistors 125 to 133, and inverters 134 to 136. The inverter 134 inverts the signal SEN given from the control circuit. In the MOS transistors 120 and 121, the sources are connected to the voltage VSS, the output (signal /SEN) of the inverter 134 is input to the gates, and the drains are connected to nodes N3 and N4, respectively. Hereinafter the potentials at the nodes N3 and N4 are referred to as VL and VR, respectively.

In the MOS transistor 122, the source is connected to the voltage VSS, the drain is connected to the node N3, and the gate is connected to the drain of the MOS transistor 123. In the MOS transistor 123, the source is connected to the voltage VSS, the drain is connected to the node N4, and the gate is connected to the drain of the MOS transistor 122. In the MOS transistor 125, the drain is connected to the drain of the MOS transistor 122, i.e., to the gate of the MOS transistor 123, and the gate is connected to the gate of the MOS transistor 122, i.e., to the drain of the MOS transistor 123. In the MOS transistor 126, the drain is connected to the drain of the MOS transistor 123, i.e., to the gate of the MOS transistor 122, and the gate is connected to the gate of the MOS transistor 123, i.e., to the drain of the MOS transistor 122. In the MOS transistor 124, the output of the inverter 134 is input to the gate, one of the source and the drain is connected to the gate of the MOS transistor 125, and the other is connected to the gate of the MOS transistor 126.

In the MOS transistor 127, the gate is connected to the data line DL and the drain is connected to the source of the MOS transistor 125. In the MOS transistor 128, the signal S1 is input to the gate and the drain is connected to the source of the MOS transistor 125. In the MOS transistor 129, the gate is connected to the data line DL and the drain is connected to the source of the MOS transistor 128. In the MOS transistor 130, the gate is connected to the reference data line DLR and the drain is connected to the source of the MOS transistor 126. In the MOS transistor 131, the signal S2 is input to the gate and the drain is connected to the source of the MOS transistor 126. In the MOS transistor 132, the gate is connected to the reference data line DLR and the drain is connected to the source of the MOS transistor 131. In the MOS transistor 133, the output of the inverter 134 is input to the gate, the drain is connected to the sources of the MOS transistors 127, 129, 130, and 132, and the source is connected to the voltage VDD.

The inverters 135 and 136 invert the potentials VL and VR at the nodes N3 and N4, respectively. The outputs of the inverters 135 and 136 are input to the NAND gates 90 and 91, respectively, of the output unit 53. The output unit 53 has the same configuration as the first embodiment.

Thus, the differential amplifying unit 52 of the fourth embodiment is a latch type differential amplifier in which the data read out from the memory cell MC is input to the first gate (gates of the MOS transistors 127 and 129) while the reference data read out from the reference cell is input to the second gate (gates of the MOS transistors 130 and 132). The number of current paths controlled by the potential at the first gate and the number of current paths controlled by the potential at the second gate are controlled by the signals S1 and S2. That is, the current path formed by the MOS transistors 128 and 129 and the current path formed by the MOS transistors 131 and 132 act as the offset current path for each of the current paths formed by the MOS transistors 127 and 130, respectively.

The control unit 54 generates the signals S1 and S2 as shown in FIG. 22. FIG. 22 is a diagram showing the signals S1 and S2 during the first and second sense operations. As shown in FIG. 22, the control unit 54 sets the signals S1 and S2 to the “H” level during the first sense operation. During the second sense operation, the control unit 54 sets the signals S1 and S2 to the “L” level and “H” level, respectively, when the higher-order bit is the “0” data, and sets the signals S1 and S2 to the “H” level and “L” level, respectively, when the lower bit is the “1” data.

Because other configurations of the fourth embodiments are similar to those of the first embodiment, the description is omitted.

The operation of the sense amplifier 50 during the data readout is substantially similar to that of FIG. 18 in the second embodiment except for the control method in the control unit 54. That is, because the control unit 54 sets the signals S1 and S2 to the “H” level after Step S11, the MOS transistors 128 and 131 are turned off. As a result, the one current path (formed by the MOS transistor 127) is controlled by the potential at the data line DL, and the one current path (formed by the MOS transistor 130) is controlled by the potential at the reference data line DLR. Therefore, the first reference level is obtained (Step S20), and the determination of the higher-order bit of the data is made using the first reference level (Step S13).

As a result of Step S13, when the higher-order bit is the “0” data (YES in Step S14), the control unit 54 sets the signals S1 and S2 to the “L” level and “H” level, respectively, whereby the MOS transistor 128 is turned on while the MOS transistor 131 is turned off. That is, the ratio of the current path controlled by the potential at the data line DL and the current path controlled by the potential at the reference data line DLR becomes 2:1, thereby obtaining the second reference level (Step S16). The second reference level is obtained by raising the first reference level, and VDL(11)<VDL(10)<VDL(01)<second reference level<VDL(00) holds. The determination of the lower bit of the data is made using the second reference level (Step S17).

As a result of Step S13, when the higher-order bit is the “1” data (NO in Step S14), the control unit 54 sets the signals S1 and S2 to the “H” level and “L” level, respectively, whereby the MOS transistor 128 is turned off while the MOS transistor 131 is turned on. That is, the ratio of the current path controlled by the potential at the data line DL and the current path controlled by the potential at the reference data line DLR becomes 1:2, thereby obtaining the second reference level (Step S19). The second reference level is obtained by lowering the first reference level, and VDL(11)<second reference level<VDL(10)<VDL(01)<VDL(00) holds. The determination of the lower bit of the data is made using the second reference level (Step S17).

The same effect as the first embodiment is also obtained in the configuration of the fourth embodiment.

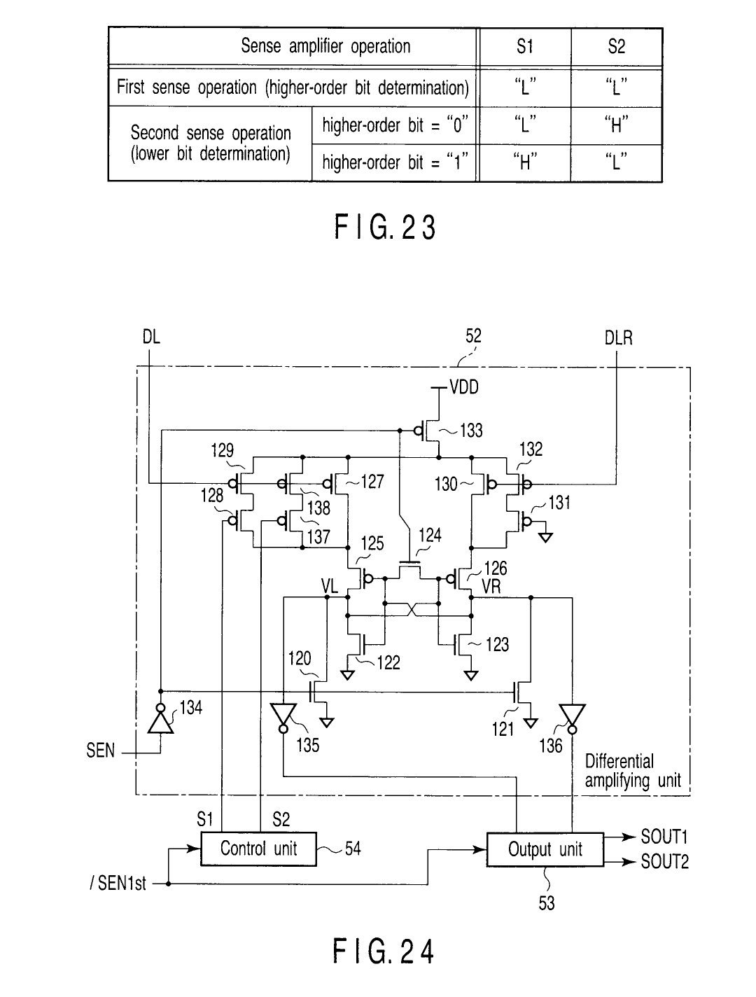

Instead of the diagram of FIG. 22, the control unit 54 may control the signals S1 and S2 as shown in FIG. 23. FIG. 23 is a diagram showing the signal S1 and S2 during the first and second sense operations.

As shown in FIG. 23, the control unit 54 sets the signals S1 and S2 to the “L” level during the first sense operation. During the second sense operation, the control unit 54 sets the signals S1 and S2 to the “L” level and “H” level, respectively, when the higher-order bit is the “0” data, and sets the signals S1 and S2 to the “H” level and “L” level, respectively, when the lower bit is the “1” data.

Also in this method, during the second sense operation, the ratio of the current path controlled by the potential at the data line DL and the current path controlled by the potential at the reference data line DLR can be set to 2:1 when the higher-order bit is the “0” data, and the ratio can be set to 1:2 when the higher-order bit is the “1” data.

### Fifth Embodiment

A semiconductor memory device according to a fifth embodiment of the invention will be described below. In the fifth embodiment, the current path controlled by the potential at the reference data line DLR in the fourth embodiment is kept constant, and the offset amount of the current path controlled by the potential at the data line DL in the fourth embodiment is changed to obtain the second reference level. Other configurations are similar to those of the fourth embodiment. In other words, in the fifth embodiment, the n-channel MOS transistor is replaced with the p-channel MOS transistor in the gate input unit of the differential amplifying unit 52 in the second embodiment. FIG. 24 is a circuit diagram partially showing a configuration of the sense amplifier 50 included in the NOR type flash memory according to the fifth embodiment.

As shown in FIG. 24, in the differential amplifying unit 52 of the sense amplifier 50, the configuration of FIG. 21 described in the fourth embodiment is modified as follows. In the differential amplifying unit 52, the gate of the MOS transistor 131 is connected to the voltage VSS. Accordingly, the MOS transistor 131 is always turned on during the first sense operation and second sense operation.

P-channel MOS transistors 137 and 138 are added. In the MOS transistor 137, the drain is connected to the source of the MOS transistor 125, the source is connected to the drain of the MOS transistor 138, and the signal S2 is input to the gate. In the MOS transistor 138, the source is connected to the drain of the MOS transistor 133 and the gate is connected to the data line DL. That is, the current path of the MOS transistors 137 and 138 is added as the offset of the current path through which the current is passed according to the potential at the data line DL.

The control unit 54 generates the signals S1 and S2 as shown in FIG. 17 in the second embodiment. That is, the control unit 54 sets the signals S1 and S2 to the “H” level and “L” level, respectively, during the first sense operation. During the second sense operation, the control unit 54 sets the signals S1 and S2 to the “L” level when the higher-order bit is the “0” data, and sets the signals S1 and S2 to the “H” level when the lower bit is the “1” data.

The operation of the sense amplifier 50 during the data readout is substantially similar to that of FIG. 18 in the second embodiment except for the control method in the control unit 54. That is, because the control unit 54 sets the signals S1 and S2 to the “H” level and “L” level, respectively, after Step S11, the MOS transistor 128 is turned off and the MOS transistor 137 is turned on. Accordingly, the ratio of the current path controlled by the potential at the data line DL and the current path controlled by the potential at the reference data line DLR becomes 2:2, thereby obtaining the first reference level (Step S20). The determination of the higher-order bit of the data is made using the first reference level (Step S13).

As a result of Step S13, when the higher-order bit is the “0” data (YES in Step S14), the control unit 54 sets the signals S1 and S2 to the “L” level, whereby the MOS transistors 128 and 137 are turned on. That is, the ratio of the current path controlled by the potential at the data line DL and the current path controlled by the potential at the reference data line DLR becomes 3:2, thereby obtaining the second reference level (Step S16). The second reference level is obtained by raising the first reference level, and VDL(11)<VDL(11)<VDL(01)<second reference level<VDL(00) holds. The determination of the lower bit of the data is made using the second reference level (Step S17).

As a result of Step S13, when the higher-order bit is the “1” data (NO in Step S14), the control unit 54 sets the signals S1 and S2 to the “H” level, whereby the MOS transistors 128 and 137 are turned off. That is, the ratio of the current path controlled by the potential at the data line DL and the current path controlled by the potential at the reference data line DLR becomes 1:2, thereby obtaining the second reference level (Step S19). The second reference level is obtained by lowering the first reference level, and VDL(11)<second reference level<VDL(10)<VDL(01)<VDL(00) holds. The determination of the lower bit of the data is made using the second reference level (Step S17).

The same effect as the first embodiment is also obtained in the configuration of the fifth embodiment.

### Sixth Embodiment

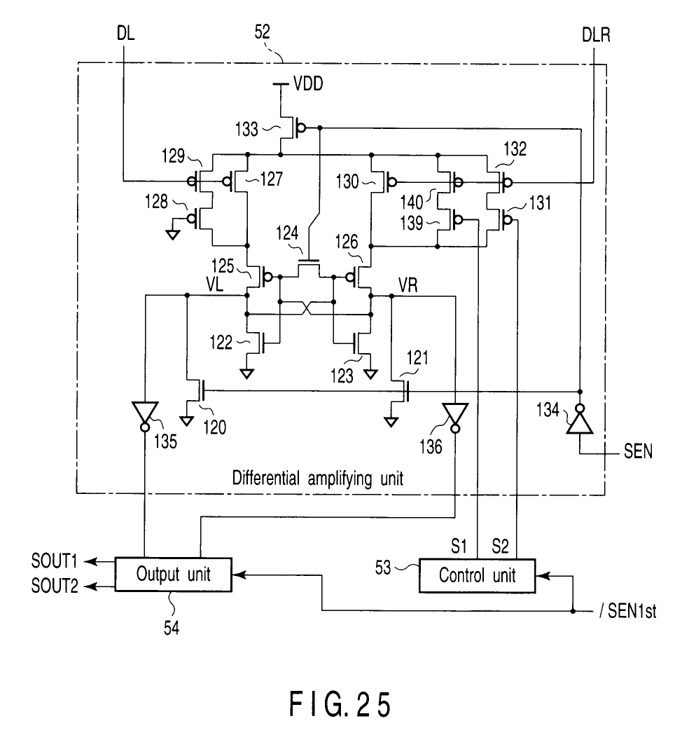

A semiconductor memory device according to a sixth embodiment of the invention will be described below. In the sixth embodiment, the current path controlled by the potential at the data line DL in the fourth embodiment is kept constant, and the offset amount of the current path controlled by the potential at the reference data line DLR in the fourth embodiment is changed to obtain the second reference level. Other configurations are similar to those of the fourth embodiment. In other words, in the sixth embodiment, the n-channel MOS transistor is replaced with the p-channel MOS transistor in the gate input unit of the differential amplifying unit 52 in the third embodiment. FIG. 25 is a circuit diagram partially showing a configuration of the sense amplifier 50 included in the NOR type flash memory according to the sixth embodiment.

As shown in FIG. 25, in the differential amplifying unit 52 of the sense amplifier 50, the configuration of FIG. 21 described in the fourth embodiment is modified as follows. In the differential amplifying unit 52, the gate of the MOS transistor 128 is connected to the voltage VSS. Accordingly, the MOS transistor 128 is always turned on during the first sense operation and second sense operation.

P-channel MOS transistors 139 and 140 are added. In the MOS transistor 139, the drain is connected to the source of the MOS transistor 126, the source is connected to the drain of the MOS transistor 140, and the signal S1 is input to the gate. In the MOS transistor 140, the source is connected to the drain of the MOS transistor 133 and the gate is connected to the reference data line DLR. That is, the current path of the MOS transistors 139 and 140 is added as the offset of the current path through which the current is passed according to the potential at the reference data line DLR.

The control unit 54 generates the signals S1 and S2 as shown in FIG. 20 of the third embodiment. That is, the control unit 54 sets the signals S1 and S2 to the “H” level and “L” level, respectively, during the first sense operation. During the second sense operation, the control unit 54 sets the signals S1 and S2 to the “H” level when the higher-order bit is the “0” data, and sets the signals S1 and S2 to the “L” level when the higher-order bit is the “1” data.

The operation of the sense amplifier 50 during the data readout is substantially similar to that of FIG. 18 in the second embodiment except for the control method in the control unit 54. That is, because the control unit 54 sets the signals S1 and S2 to the “H” level and “L” level, respectively, after Step S11, the MOS transistor 139 is turned off and the MOS transistor 131 is turned on. Accordingly, the ratio of the current path controlled by the potential at the data line DL and the current path controlled by the potential at the reference data line DLR becomes 2:2, thereby obtaining the first reference level (Step S20). The determination of the higher-order bit of the data is made using the first reference level (Step S13).

As a result of Step S13, when the higher-order bit is the “0” data (YES in Step S14), the control unit 54 sets the signals S1 and S2 to the “H” level, whereby the MOS transistors 139 and 131 are turned off. That is, the ratio of the current path controlled by the potential at the data line DL and the current path controlled by the potential at the reference data line DLR becomes 2:1, thereby obtaining the second reference level (Step S16). The second reference level is obtained by raising the first reference level, and VDL(11)<VDL(10)<VDL(01)<second reference level<VDL(00) holds. The determination of the lower bit of the data is made using the second reference level (Step S17).

As a result of Step S13, when the higher-order bit is the “1” data (NO in Step S14), the control unit 54 sets the signals S1 and S2 to the “L” level, whereby the MOS transistors 139 and 131 are turned on. That is, the ratio of the current path controlled by the potential at the data line DL and the current path controlled by the potential at the reference data line DLR becomes 2:3, thereby obtaining the second reference level (Step S19). The second reference level is obtained by lowering the first reference level, and VDL(11)<second reference level<VDL(10)<VDL(01)<VDL(00) holds. The determination of the lower bit of the data is made using the second reference level (Step S17).

The same effect as the first embodiment is also obtained in the configuration of the sixth embodiment.

### Seventh Embodiment

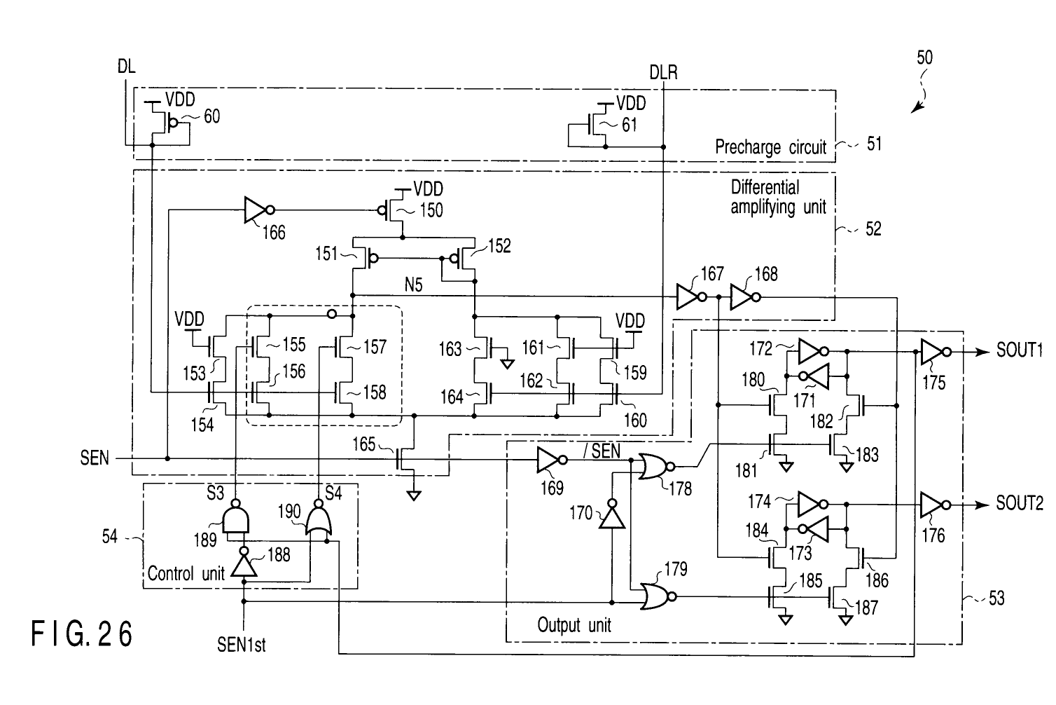

A semiconductor memory device according to a seventh embodiment of the invention will be described below. In the seventh embodiment, a current mirror type differential amplifier is applied to the sense amplifier 50 of the first embodiment. Because other configurations are similar to those of the first embodiment except for the configuration of the sense amplifier 50, description is omitted. FIG. 26 is a circuit diagram showing the sense amplifier 50 included in the NOR type flash memory according to the seventh embodiment.

As shown in FIG. 26, the sense amplifier 50 includes the precharge circuit 51, the differential amplifying unit 52, the output unit 53, and the control unit 54. The precharge circuit 51 has the configuration similar to that of FIG. 3 in the first embodiment.

The differential amplifying unit 52 includes p-channel MOS transistors 150 to 152, n-channel MOS transistors 153 to 165, and inverters 166 to 168. The inverter 166 inverts the sense amplifier enable signal SEN given from a control circuit (not shown). In the MOS transistor 150, the source is connected to the voltage VDD and the output of the inverter 166 is input to the gate. In the MOS transistor 151, the source is connected to the drain of the MOS transistor 150 and the gate is connected to the gate of the MOS transistor 152. In the MOS transistor 152, the source is connected to the drain of the MOS transistor 150 and the gate and drain are commonly connected.

In the MOS transistor 153, the voltage VDD is given to the gate and the drain is connected to the drain of the MOS transistor 151. In the MOS transistor 154, the gate is connected to the data line DL and the drain is connected to the source of the MOS transistor 153. In the MOS transistor 155, a signal S3 given from the control unit 54 is input to the gate and the drain is connected to the drain of the MOS transistor 151. In the MOS transistor 156, the gate is connected to the data line DL and the drain is connected to the source of the MOS transistor 155. In the MOS transistor 157, a signal S4 given from the control unit 54 is input to the gate and the drain is connected to the drain of the MOS transistor 151. In the MOS transistor 158, the gate is connected to the data line DL and the drain is connected to the source of the MOS transistor 157. Hereinafter, a connection node of the drain of the MOS transistor 151 and the drains of the MOS transistors 153, 155, and 157 is referred to as node N5.

In the MOS transistors 159 and 161, the voltage VDD is given to the gates and the drains are connected to the drain of the MOS transistor 152. In the MOS transistors 160 and 162, the gates are connected to the reference data line DLR and the drains are connected to the sources of the MOS transistors 159 and 161, respectively. In the MOS transistor 163, the voltage VSS is given to the gate and the drain is connected to the drain of the MOS transistor 152. In the MOS transistor 164, the gate is connected to the reference data line DLR and the drain is connected to the source of the MOS transistor 163.

In the MOS transistor 165, the signal SEN is input to the gate, the drain is connected to the sources of the MOS transistors 154, 156, 158, 160, 162, and 164, and the voltage VSS is given to the source. The inverter 167 inverts the potential at the node N5 and the inverter 168 inverts the output of the inverter 167.

Thus, the differential amplifying unit 52 of the fourth embodiment is a current mirror type differential amplifier in which the data read out from the memory cell MC is input to the first gate (gates of the MOS transistors 154, 156, and 158) while the reference data read out from the reference cell is input to the second gate (gates of the MOS transistors 160 and 162). The number of current paths controlled by the potential at the first gate is controlled by the signals S3 and S4. That is, the current path formed by the MOS transistors 155 and 156 and the current path formed by the MOS transistors 157 and 158 act as the offset current path for the current path formed by the MOS transistors 153 and 154.

The output unit 53 includes inverters 169 to 176, NOR gates 178 and 179, and n-channel MOS transistors 180 to 187.

The inverter 169 inverts the signal SEN. The inverter 170 inverts a signal SEN1st given from the control circuit (not shown). The signal SEN1st is set to the “H” level in the first sense operation while the signal SEN1st is set to the “L” level in the second sense operation. The NOR gate 178 performs a NOR operation of the output of the inverter 169 and the output of the inverter 170. The NOR gate 179 performs a NOR operation of the output of the inverter 169 and the signal SEN1st.

In the MOS transistors 180 and 182, the gates are connected to the output nodes of the inverters 167 and 168, respectively, and the sources are connected to the drains of the MOS transistors 181 and 183, respectively. In the MOS transistors 181 and 183, the gates are connected to the output node of the NOR gate 178 and the sources are connected to the voltage VSS. In the inverter 171, the input node is connected to the drain of the MOS transistor 182 and the output node is connected to the drain of the MOS transistor 180. In the inverter 172, the input node is connected to the drain of the MOS transistor 180, i.e., to the output node of the inverter 171, and the output node is connected to the drain of the MOS transistor 182, i.e., to the input node of the inverter 171.

The inverter 175 inverts the level at the connection node of the output node of the inverter 172 and the input node of the inverter 171, and outputs the inversion result as the signal SOUT1 (higher-order bit data).

In the MOS transistors 184 and 186, the gates are connected to the output nodes of the inverters 167 and 168 and the sources are connected to the drains of the MOS transistors 185 and 187, respectively. In the MOS transistors 185 and 187, the gates are connected to the output node of the NOR gate 179 and the sources are connected to the voltage VSS. In the inverter 173, the input node is connected to the drain of the MOS transistor 186 and the output node is connected to the drain of the MOS transistor 184. In the inverter 174, the input node is connected to the drain of the MOS transistor 184, i.e., to the output node of the inverter 173, and the output node is connected to the drain of the MOS transistor 186, i.e., to the input node of the inverter 173.

The inverter 176 inverts the level at the connection node of the output node of the inverter 174 and the input node of the inverter 173, and outputs the inversion result as the signal SOUT2 (lower bit data).

Next, the control unit 54 will be described. The control unit 54 includes an inverter 188, a NAND gate 189, and a NOR gate 190. The inverter 188 inverts the signal SEN1st. The NAND gate 189 performs the NAND operation of the output of the inverter 188 and the output of the inverter 172 in the output unit 53, and outputs the operation result as the signal S3 to the differential amplifying unit 52. The NOR gate 190 performs the NAND operation of the signal SEN1st and the output of the inverter 172 in the output unit 53, and outputs the operation result as the signal S4 to the differential amplifying unit 52.

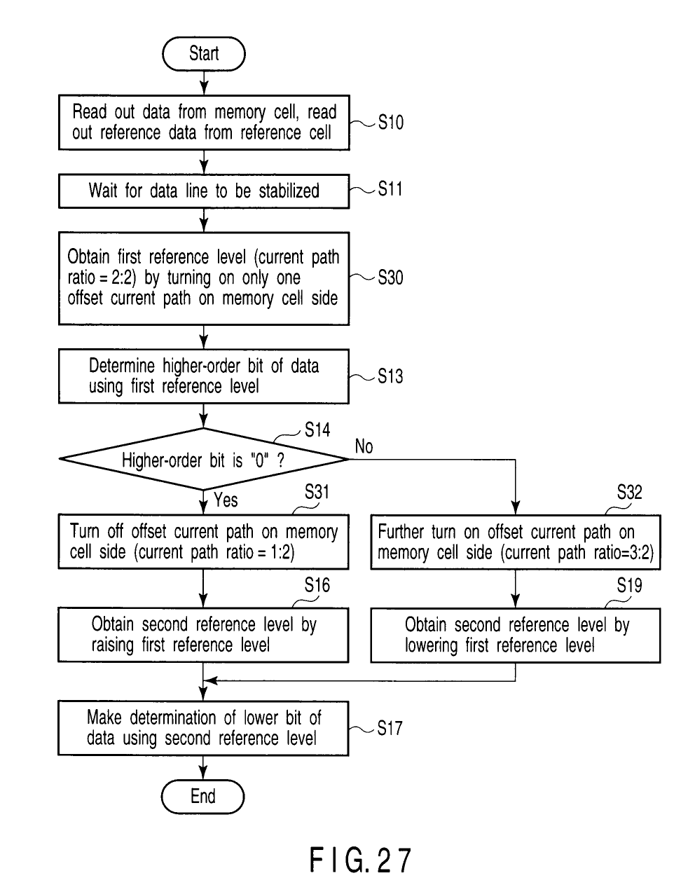

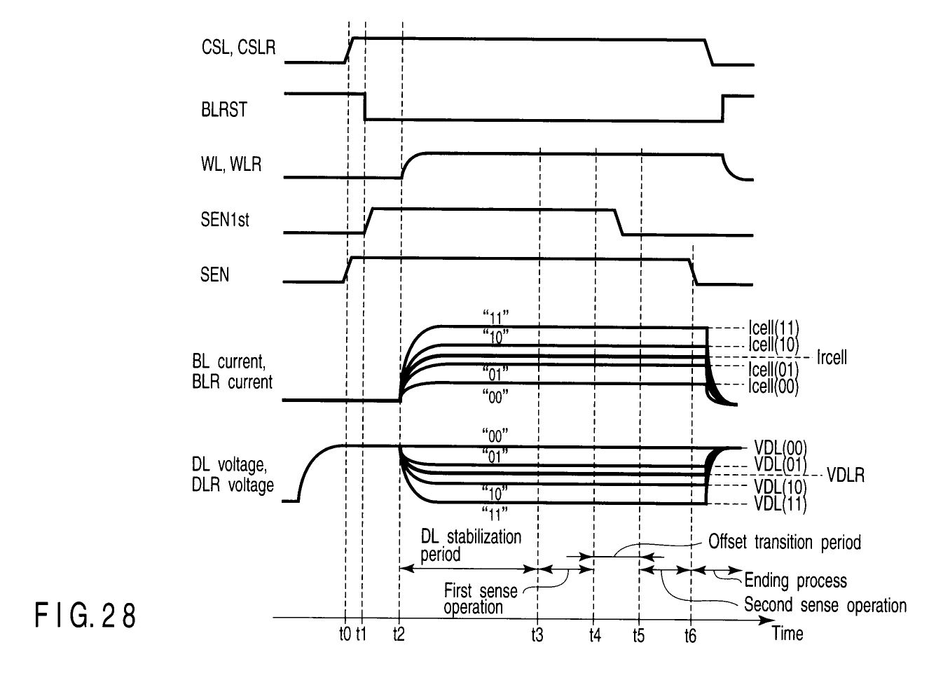

Focusing particularly on an operation performed by the read circuit 17, a data readout method in the flash memory 10 according to the seventh embodiment will be described below with reference to FIGS. 27 and 28. FIG. 27 is a flowchart showing the data readout operation of the read circuit 17, and FIG. 28 is a timing chart showing changes in potentials at the column selection lines CSL and CSLR, a signal BLRST, word lines WL and WLR, a signal SEN1st, and a signal SEN, changes in currents of a bit line BL and a reference bit line BLR, and changes in potentials at a data line DL and a reference data line DLR.

In reading out the data, first, the data line DL and reference data line DLR are precharged at predetermined precharge potentials. At the time t0, the “H” level is given to the column selection lines CSL and CSLR, and the signal SEN is set to the “H” level. At the time t1, the signal BLRST is set to the “L” level and the signal SEN1st is set to the “H” level.

The data is read out from the memory cell MC to the bit line BL, and the reference data is read out from the reference cell 31 to the reference bit line BLR (time t2 in Step S10).

Then, the read circuit 17 waits for the potential to be stabilized at the data line DL (time t2 to t3, Step S11). The differential amplifying unit 52 turns on only one offset current path on the memory cell side to obtain the first reference level (Step S30). Because the signal SEN1st is set to the “H” level, the signals S3 and S4 become the “H” level and “L” level, respectively, whereby the MOS transistor 155 is turned on while the MOS transistor 157 is turned off. That is, only the one offset current path is enabled in the two current paths (the current path formed by the MOS transistors 155 and 156 and the current path formed by the MOS transistors 157 and 158). Accordingly, the ratio of the number of current paths controlled by the data line DL and the number of the current paths controlled by the reference data line DLR becomes 2:2. The first sense operation is performed after the period for stabilizing the data line DL elapses.

When the first sense operation is ended, the control circuit sets the signal SEN1st to the “L” level. As a result of Step S13, when the higher-order bit is the “0” data (YES in Step S14), the control unit 54 sets the signals S3 and S4 to the “L” level. That is, the two offset current paths are disabled, and the ratio of the number of current paths controlled by the data line DL and the number of the current paths controlled by the reference data line DLR becomes 1:2 (Step S31). This enables the differential amplifying unit 52 to obtain the second reference level, higher than the first reference level (Step S16). The second reference level is the potential located between the voltages VDL(00) and VDL(01) in FIG. 7. The differential amplifying unit 52 determines the lower bit of the data based on the second reference level (time t5 to t6, Step S17).

As a result of Step S14, when the higher-order bit is the “1” data (NO in Step S14), the control unit 54 sets the signals S3 and S4 to the “H” level. That is, the two offset current paths are enabled, and the ratio of the number of current paths controlled by the data line DL and the number of the current paths controlled by the reference data line DLR becomes 3:2 (Step S32). This enables the differential amplifying unit 52 to obtain the second reference level, lower than the first reference level (Step S19). The second reference level is the potential located between the voltages VDL(11) and VDL(10) in FIG. 7. The differential amplifying unit 52 determines the lower bit of the data based on the second reference level (clock times t5 and t6 in Step S17).

A specific example of the operation performed by the read circuit 17 during the data readout operation will be described below.

(“00” Data Readout)

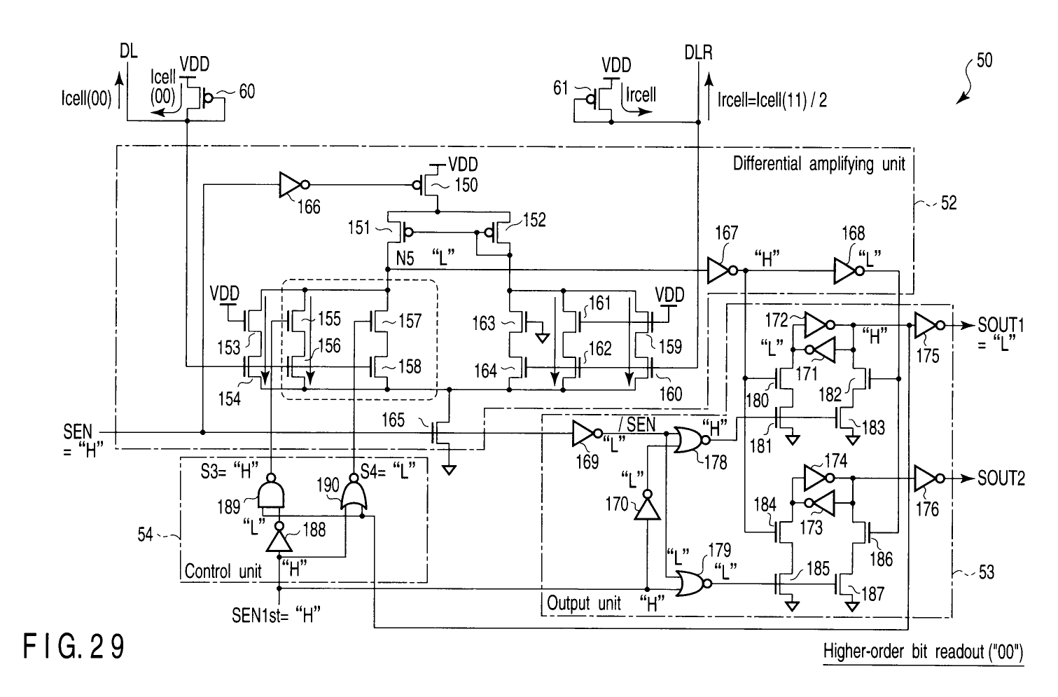

FIG. 29 is circuit diagrams showing the read circuit 17, and shows the first sense operation when the “00” data is read out. As shown in FIG. 29, the current Icell(00) is passed through the bit line BL and the potential at the data line DL is the voltage VDL(00). The current Ircell=Icell(11)/2 is passed through the reference bit line BLR and the potential at the reference data line DLR is the voltage VDLR=VDL(00)/2. The signal SEN is set to the “H” level and the signal SEN1st is set to the “H” level.

Accordingly, because the outputs (signals S1 and S2) of the NAND gate 189 and NOR gate 190 in the control unit 54 become the “H” level and “L” level, respectively, the MOS transistor 155 is turned on while the MOS transistor 157 is turned off. That is, the differential amplifying unit 52 obtains the first reference level. The first reference level is VDL(11)<VDL(10)<first reference level<VDL(01)<VDL(00). Because of VDL(00)>>VDLR, i.e., VDL(00)>first reference level, the node N5 becomes the “L” level.

In the output unit 53, the outputs of the NOR gates 178 and 179 become the “H” level and “L” level, respectively, whereby the MOS transistors 181 and 183 are turned on, and the MOS transistors 185 and 187 are turned off. That is, the latch circuit formed by the inverters 171 and 172 becomes a state in which the data can be captured.

Because the outputs of the inverters 167 and 168 exist at the “H” level and “L” level, respectively, the MOS transistor 180 is turned on and the MOS transistor 182 is turned off. Accordingly, the potentials at the input node of the inverter 171 and the output node of the inverter 172 become the “H” level. Accordingly, the signal SOUT1 becomes the “L” level to output the higher-order bit of “0”.

Then, the second sense operation is performed to make the determination of the lower bit. FIG. 30 is a circuit diagram showing the read circuit 17, and shows the second sense operation when the “00” data is read out. As shown in FIG. 30, in performing the second sense operation, the signal SEN1st is set to the “L” level. The output node of the inverter 172 is set to the “H” level.

Therefore, in the control unit 54, the outputs of the NAND gate 189 and NOR gate 190 become the “L” level. Therefore, in the differential amplifying unit 52, the MOS transistors 156 and 158 are turned off. This enables the differential amplifying unit 52 to obtain the second reference level, higher than the first reference level. The second reference level is VDL(11)<VDL(10)<VDL(01)<second reference level<VDL(00). Because of VDL(00)>>VDLR and VDL(00)>second reference level, the current passed through the MOS transistors 153 and 154 is higher than the sum of the current passed through the MOS transistors 159 and 160 and the current passed through the MOS transistors 161 and 162. Accordingly, the node N5 is maintained at the “L” level.

In the output unit 53, because the outputs of the NOR gates 178 and 179 become the “L” level and “H” level, respectively, the MOS transistors 181 and 183 are turned off and the MOS transistors 185 and 187 are turned on. That is, the latch circuit formed by the inverters 173 and 174 becomes the state in which the data can be captured.

Because the outputs of the inverters 167 and 168 become the “H” level and “L” level, respectively, the MOS transistor 184 is turned on and the MOS transistor 186 is turned off. Accordingly, the potentials at the input node of the inverter 173 and the output node of the inverter 174 become the “H” level. Accordingly, the signal SOUT2 becomes the “L” level to output the lower bit of “0”.

The determination of the difference between the higher-order bit of “0” and lower bit of “0” is made by the above-described operation.

(“11” Data Readout)

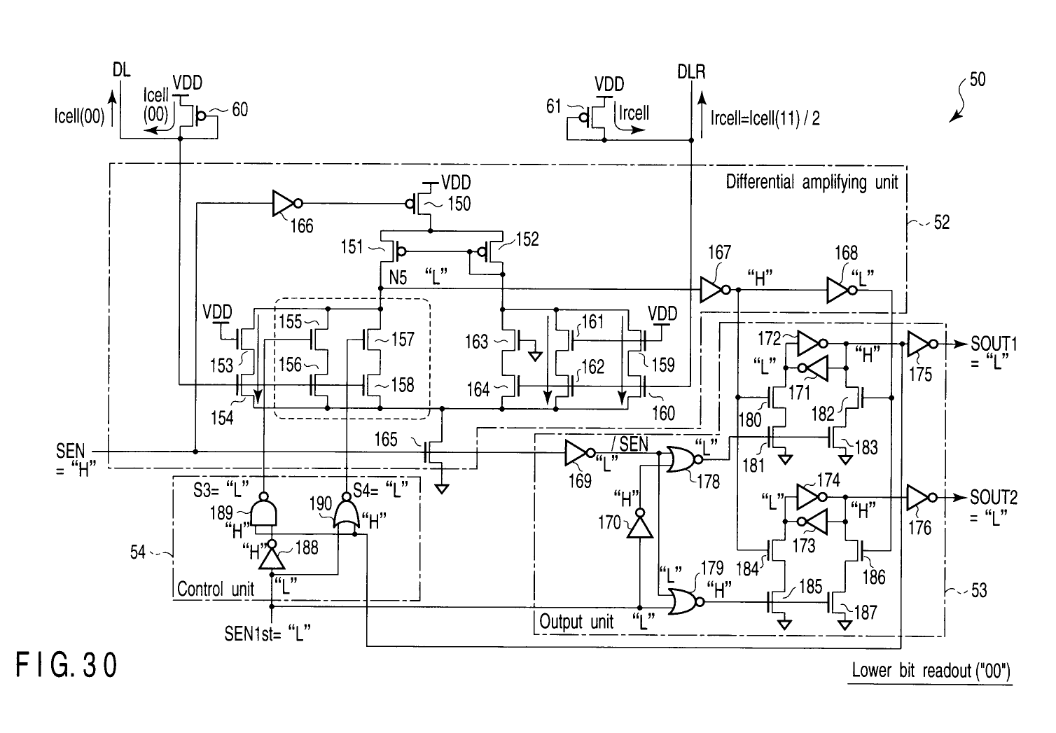

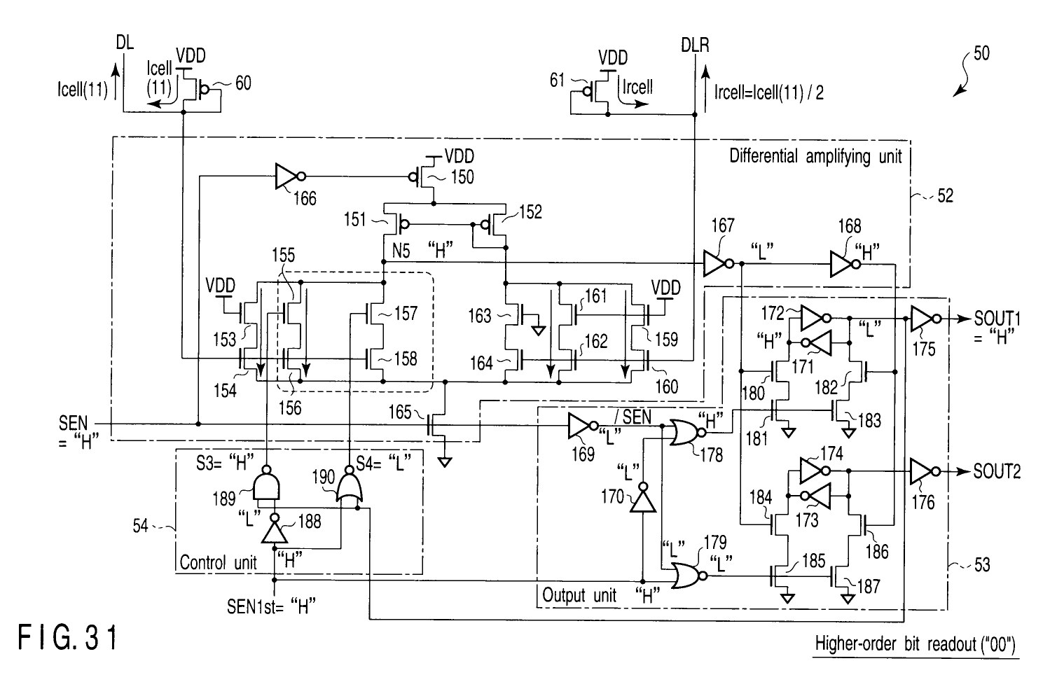

FIG. 31 is a circuit diagram showing the read circuit 17, and shows the first sense operation when the “11” data is read out. As shown in FIG. 31, the current Icell(11) is passed through the bit line BL and the potential at the data line DL is the voltage VDL(11).

In the first sense operation, similarly to the case of FIG. 29, because the outputs (signals S3 and S4) of the NAND gate 189 and NOR gate 190 become the “H” level and “L” level, respectively, the differential amplifying unit 52 obtains the first reference level. The first reference level is VDL(11)<VDL(10)<first reference level<VDL(01)<VDL(00). Because of VDL(11)<<VDLR, i.e., VDL(11)<<first reference level, the node N5 becomes the “H” level.

In the output unit 53, the outputs of the NOR gates 178 and 179 become the “H” level and “L” level, respectively, whereby the latch circuit formed by the inverters 171 and 172 becomes the state in which the data can be captured. Because the outputs of the inverters 167 and 168 exist at the “L” level and “H” level, respectively, the MOS transistor 182 is turned on and the MOS transistor 180 is turned off. Accordingly, the potentials at the input node of the inverter 171 and the output node of the inverter 172 become the “L” level. Accordingly, the signal SOUT1 becomes the “H” level to output the higher-order bit of “1”.

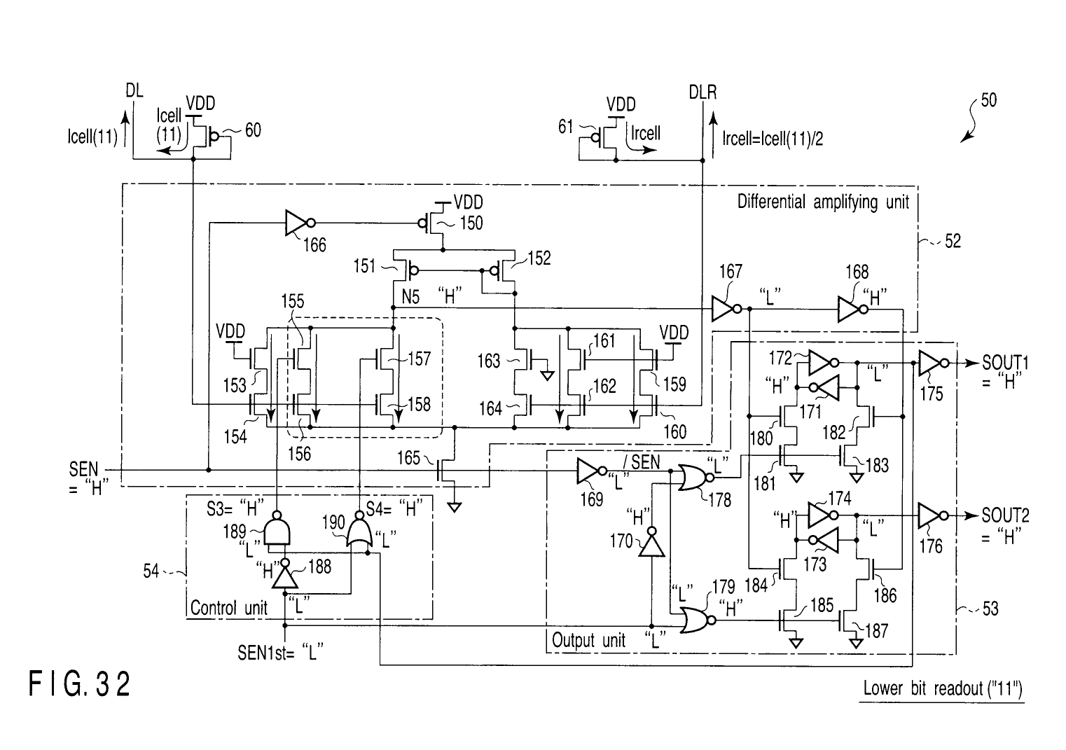

Then, the second sense operation is performed to make the determination of the lower bit. FIG. 32 is a circuit diagram showing the read circuit 17, and shows the second sense operation when the “11” data is read out. As shown in FIG. 32, in performing the second sense operation, the signal SEN1st is set to the “L” level. The output node of the inverter 172 is set to the “L” level.

Therefore, in the control unit 54, the outputs of the NAND gate 189 and NOR gate 190 become the “H” level. Therefore, in the differential amplifying unit 52, the MOS transistors 156 and 158 are turned on. This enables the differential amplifying unit 52 to obtain the second reference level, lower than the first reference level. The second reference level is VDL(11)<second reference level<VDL(10)<VDL(01)<VDL(00). Because of VDL(11)<<VDLR and VDL(11)<second reference level, the node N5 is maintained at the “H” level.

Because the outputs of the NOR gates 178 and 179 become the “L” level and “H” level, respectively, the latch circuit formed by the inverters 173 and 174 becomes the state in which the data can be captured. Because the outputs of the inverters 167 and 168 become the “L” level and “H” level, respectively, the MOS transistor 186 is turned on and the MOS transistor 184 is turned off. Accordingly, the potentials at the input node of the inverter 173 and the output node of the inverter 174 become the “L” level. Accordingly, the signal SOUT2 becomes the “H” level to output the lower bit of “1”.

The determination of the difference between the higher-order bit of “1” and lower bit of “1” is made by the above-described operation.

The same effect as the first embodiment is also obtained in the configuration of the seventh embodiment.

### Eighth Embodiment

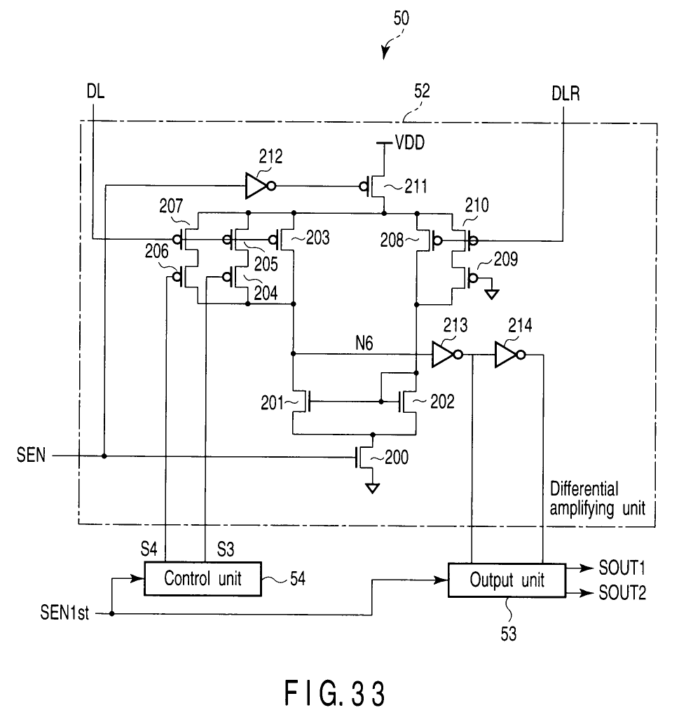

A semiconductor memory device according to an eighth embodiment of the invention will be described below. In the eighth embodiment, the n-channel MOS transistor is replaced with the p-channel MOS transistor in the input of the gate of the differential amplifying unit 52 in the sense amplifier 50 described in the seventh embodiment. Because other configurations are similar to those of the seventh embodiment, description thereof is omitted. FIG. 33 is a circuit diagram showing a part of the sense amplifier 50 included in the NOR type flash memory according to the eighth embodiment.

As shown in FIG. 33, the differential amplifying unit 52 includes n-channel MOS transistors 200 to 202, p-channel MOS transistors 203 to 210, and inverters 212 to 214. The inverter 212 inverts the signal SEN. In the MOS transistor 200, the source is connected to the voltage VSS and the signal SEN is input to the gate. In the MOS transistor 201, the source is connected to the drain of the MOS transistor 200 and the gate is connected to the gate of the MOS transistor 202. In the MOS transistor 202, the source is connected to the drain of the MOS transistor 200, and the gate and drain are commonly connected.

In the MOS transistor 203, the gate is connected to the data line DL and the drain is connected to the drain of the MOS transistor 201. In the MOS transistor 204, the signal S3 given from the control unit 54 is input to the gate and the drain is connected to the drain of the MOS transistor 201. In the MOS transistor 205, the gate is connected to the data line DL and the drain is connected to the source of the MOS transistor 204. In the MOS transistor 206, the signal S4 given from the control unit 54 is input to the gate and the drain is connected to the drain of the MOS transistor 201. In the MOS transistor 207, the gate is connected to the data line DL and the drain is connected to the source of the MOS transistor 206. Hereinafter, the connection node of the drain of the MOS transistor 201 and the drains of the MOS transistors 203, 204, and 206 is referred to as node N6.

In the MOS transistor 208, the gate is connected to the reference data line DLR and the drain is connected to the drain of the MOS transistor 202. In the MOS transistor 209, the gate is connected to the voltage VSS and the drain is connected to the drain of the MOS transistor 202. In the MOS transistor 210, the gate is connected to the reference data line DLR and the drain is connected to the source of the MOS transistor 209.

In the MOS transistor 211, the output of the inverter 212 is input to the gate, the drain is connected to the sources of the MOS transistors 203, 205, 207, 208, and 210, and the source is given the voltage VDD. The inverter 213 inverts the potential at the node N6 and the inverter 214 inverts the output of the inverter 213. The output of the inverter 213 is input to the gates of the MOS transistors 180 and 184, and the output of the inverter 214 is input to the gates of the MOS transistors 182 and 186.

Thus, the differential amplifying unit 52 of the eighth embodiment is a current mirror type differential amplifier in which the data read out from the memory cell MC is input to the first gate (gates of the MOS transistors 203, 205, and 207) while the reference data read out from the reference cell is input to the second gate (gates of the MOS transistors 208 and 210). The number of current paths controlled by the potential at the first gate is controlled by the signals S3 and S4. That is, the current path formed by the MOS transistors 204 and 205 and the current path formed by the MOS transistors 206 and 207 act as the offset current path for the current path formed by the MOS transistor 203.

Because other configurations of the eighth embodiments are similar to those of the first embodiment, the description thereof is omitted.

The operation of the sense amplifier 50 during the data readout is substantially similar to that of FIG. 27 in the sixth embodiment except for the control method in the control unit 54. That is, because the control unit 54 sets the signals S3 and S4 to the “H” level and the “L” level, respectively, after Step S11, the MOS transistor 204 is turned off and the MOS transistor 206 is turned on. Accordingly, the first reference level is obtained (Step S20), and the determination of the higher-order bit of the data is made using the first reference level (Step S13).

As a result of Step S13, when the higher-order bit is the “0” data (YES in Step S14), the control unit 54 sets the signals S3 and S4 to the “L” level, whereby the MOS transistors 204 and 206 are turned on. That is, the ratio of the current path controlled by the potential at the data line DL and the current path controlled by the potential at the reference data line DLR becomes 3:2, thereby obtaining the second reference level (Step S16). The second reference level is obtained by raising the first reference level, and VDL(11)<VDL(10)<VDL(01)<second reference level<VDL(00) holds. The determination of the lower bit of the data is made using the second reference level (Step S17).

As a result of Step S13, when the higher-order bit is the “1” data (NO in Step S14), the control unit 54 sets the signals S3 and S4 to the “H” level, whereby the MOS transistors 204 and 206 are turned off. That is, the ratio of the current path controlled by the potential at the data line DL and the current path controlled by the potential at the reference data line DLR becomes 1:2, thereby obtaining the second reference level (Step S19). The second reference level is obtained by lowering the first reference level, and VDL(11)<second reference level<VDL(10)<VDL(01)<VDL(00) holds. The determination of the lower bit of the data is made using the second reference level (Step S17).

The same effect as the first embodiment is also obtained in the configuration according to the eighth embodiment. The number of current paths controlled by the potential at the data line DL is changed in the seventh and eighth embodiments. However, the number of current paths controlled by the potential at the reference data line DLR may be changed as well as the number of current paths controlled by the potential at the data line DL. That is, any configuration in which the ratio of the two current paths is changed may be used.

### Ninth Embodiment

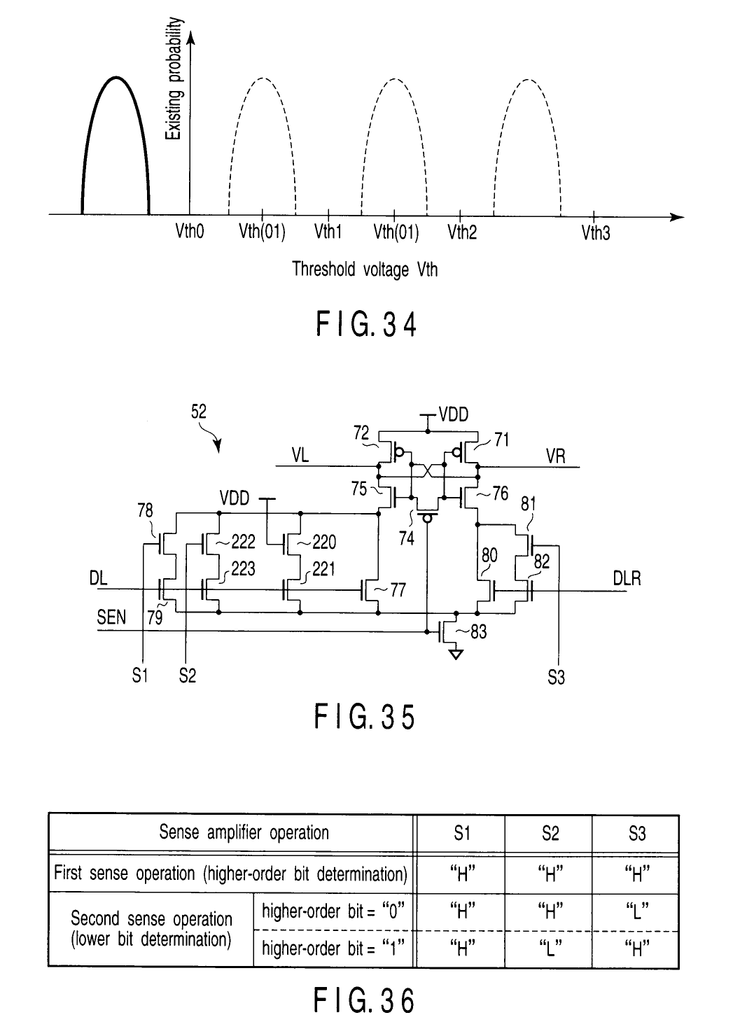

A semiconductor memory device according to a ninth embodiment of the invention will be described below. In the ninth embodiment, the threshold of the reference cell 31 in the first embodiment is changed, and the configuration of the differential amplifying unit 52 of the sense amplifier 50 is also changed with the change of the threshold. Because other configurations are similar to those of the first embodiment, the description is thereof omitted. FIG. 34 is a diagram showing a threshold distribution of the reference cell 31 according to the ninth embodiment.

As shown in FIG. 34, the reference data retained by the reference cell 31 of the ninth embodiment is equal to the “11” data, and the threshold voltage of the reference cell 31 is equal to the threshold voltage of the memory cell MC retaining the “11” data. That is, 0V<Vth<Vth0 holds for the threshold voltage Vth of the reference cell 31. Accordingly, the current Ircell=Icell(11) is passed through the reference bit line BLR in reading out the reference data. However, it is necessary that Ircell be smaller than the median of the distribution of Icell(10). Preferably, the Ircell is smaller than the minimum value of the distribution of Icell(01) or included in the distribution of Icell(11).

The voltage of VDLR=VDL(11) is generated at the reference data line DLR in reading out the reference data. However, it is necessary that VDLR be smaller than the median of the distribution of VDL(10). Preferably, the VDLR is smaller than the minimum value of the distribution of VDL(01) or included in the distribution of VDL(11).

FIG. 35 is a circuit diagram showing the differential amplifying unit 52 included in the sense amplifier 50 according to the ninth embodiment. As shown in FIG. 35, the differential amplifying unit 52 further includes MOS transistors 220 to 223 in the configuration of FIG. 3 in the first embodiment.

In the MOS transistor 220, the voltage VDD is given to the gate and the drain is connected to the drain of the MOS transistor 75. In the MOS transistor 221, the gate is connected to the data line DL, the drain is connected to the source of the MOS transistor 220, and the source is connected to the drain of the MOS transistor 83. In the MOS transistor 222, the signal S2 is given to the gate and the drain is connected to the drain of the MOS transistor 75. In the MOS transistor 223, the gate is connected to the data line DL, the drain is connected to the source of the MOS transistor 222, and the source is connected to the drain of the MOS transistor 83. The signal S3 given from the control unit 54 is input to the gate of the MOS transistor 81.

The control unit 54 generates the signals S1 to S3 as shown in FIG. 36. FIG. 36 is a diagram showing the signals S1 to S3 during the first and second sense operations. As shown in FIG. 36, the control unit 54 sets the signals S1 to S3 to the “H” level during the first sense operation. During the second sense operation, the control unit 54 sets the signals S1 and S2 to the “H” level while setting the signal S3 to the “L” level when the higher-order bit is the “0” data, and sets the signals S1 and S3 to the “H” level while setting the signal S2 to the “L” level when the higher-order bit is the “1” data.

Accordingly, the MOS transistors 78, 222, and 81 are turned on during the first sense operation. That is, the current path controlled by the potential at the data line DL includes the current path formed by the MOS transistor 77, the current path formed by the MOS transistors 78 and 79, the current path formed by the MOS transistors 220 and 221, and the current path formed by the MOS transistors 222 and 223. On the other hand, the current path controlled by the potential at the reference data line DLR includes the current path formed by the MOS transistor 80 and the current path formed by the MOS transistors 81 and 82. That is, the ratio of the current paths becomes 4:2. Therefore, VDLR=VDL(11) and the first reference level of the differential amplifying unit 52 becomes VDL(11)<VDL(10)<first reference level<VDL(01)<VDL(00). Because Ircell of the ninth embodiment becomes double the first embodiment, the current path on the reference cell side is set to a half of the current path on the memory cell side to obtain the first reference level.

During the second sense operation, when the higher-order bit is the “0” data, the MOS transistors 78 and 222 are turned on, and the MOS transistor 81 is turned off. That is, because the number of current paths controlled by the potential at the reference data line DLR is decreased by one compared with the first sense operation, the ratio of the current paths becomes 4:1. Therefore, the second reference level of the differential amplifying unit 52 becomes VDL(11)<VDL(10)<VDL(01)<second reference level<VDL(00).

During the second sense operation, when the higher-order bit is the “1” data, the MOS transistors 78 and 81 are turned on, and the MOS transistor 222 is turned off. That is, because the number of current paths controlled by the potential at the data line DL is decreased by one compared with the first sense operation, the ratio of the current paths becomes 3:2. Therefore, the second reference level of the differential amplifying unit 52 becomes VDL(11)<second reference level<VDL(10)<VDL(01)<VDL(00).

In the configuration according to the ninth embodiment, the following effect (2) is obtained in addition to the effect (1) of the first embodiment.

(2) Reliability of the Readout Operation can be Improved.

In the reference cell 31, as the size is reduced, the amount of drivable currents is decreased, namely, an absolute value of Ircell is decreased. When Ircell is decreased, an erroneous determination of the data is easily made. However, in the ninth embodiment, the double current Ircell is passed through the reference data line DLR compared with the first embodiment, so that the generation of the erroneous determination of the data can be prevented to improve the reliability of the readout operation.

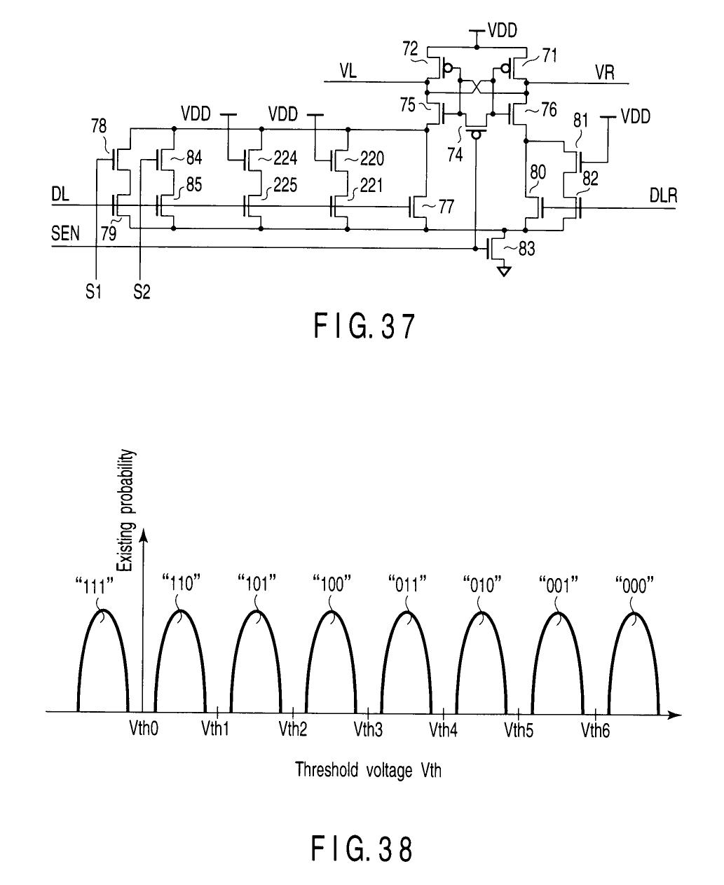

In the ninth embodiment, Ircell is set to Ircell(11) in the configuration of the first embodiment. Obviously the ninth embodiment can be applied to the configurations of the second to eighth embodiments. FIG. 37 is a circuit diagram showing the differential amplifying unit 52 of the sense amplifier 50 when the ninth embodiment is applied to the configuration of the second embodiment.

As shown in FIG. 37, the differential amplifying unit 52 further includes MOS transistors 220, 221, 224, and 225 in the configuration of FIG. 16 in the second embodiment. In the MOS transistor 220, the voltage VDD is given to the gate and the drain is connected to the drain of the MOS transistor 75. In the MOS transistor 221, the gate is connected to the data line DL, the drain is connected to the source of the MOS transistor 220, and the source is connected to the drain of the MOS transistor 83. In the MOS transistor 224, the voltage VDD is given to the gate and the drain is connected to the drain of the MOS transistor 75. In the MOS transistor 225, the gate is connected to the data line DL, the drain is connected to the source of the MOS transistor 224, and the source is connected to the drain of the MOS transistor 83. The control unit 54 generates the signals S1 and S2 as shown in FIG. 20 of the third embodiment.

Accordingly, the ratio of the current path controlled by the potential at the data line DL and the current path controlled by the potential at the reference data line DLR becomes 4:2 during the first sense operation. Therefore, the first reference level of the differential amplifying unit 52 becomes VDL(11)<VDL(10)<first reference level<VDL(01)<VDL(00).

When the higher-order bit is the “0” data, the ratio of the current paths becomes 5:2 during the second sense operation. Therefore, the second reference level of the differential amplifying unit 52 becomes VDL(11)<VDL(10)<VDL(01)<second reference level<VDL(00). When the higher-order bit is the “1” data, the ratio of the current paths becomes 3:2 during the second sense operation. Therefore, the second reference level of the differential amplifying unit 52 becomes VDL(11)<second reference level<VDL(10)<VDL(01)<VDL(00).

Thus, in the flash memory of the first to ninth embodiments, the differential amplifying unit 52 makes the determination of the data using the first reference level obtained based on the reference data read out from the reference cell 31 and the second reference level obtained by raising or lowering the first reference level inside the differential amplifying unit 52. More specifically, the differential amplifying unit 52 makes the determination of the higher-order bit in the two-bit data using the first reference level, and makes the determination of the lower bit using the second reference level.

The threshold voltage of the reference cell 31 may be located between the threshold voltage of the memory cell MC retaining the “10” data and the threshold voltage of the memory cell MC retaining the “01” data, or the threshold voltage of the reference cell 31 may be equal to the threshold voltage of the memory cell MC retaining the “11” data.

The following technique can be cited as an example of the method for obtaining the second reference level. That is, the sense amplifier includes the latch type differential amplifier in which the data is input to the first gate while the reference data is input to the second gate, and the amount of at least one of the currents passed through the current path controlled by the potential at the first gate and the current path controlled by the potential at the second gate is increased or decreased. Alternatively, the sense amplifier includes the current mirror type amplifier in which the data is input to the first gate while the reference data is input to the second gate, and the amount of at least one of the currents passed through the current path controlled by the potential at the first gate and the current path controlled by the potential at the second gate is increased or decreased. For example, the increase or decrease in the amount of current can be realized by increasing or decreasing the number of enabled current paths.

In this configuration, the determination of the data having at least two bits can be made without changing the potential at the reference data line DLR and the operating speed of the flash memory can be improved.

In the embodiments, each of the memory cells retains the two-bit data. Obviously the embodiments can be applied to the case in which each of the memory cells retains at least three-bit data. FIG. 38 is a graph showing the threshold distribution of the memory cell MC.

As shown in FIG. 38, the memory cell MC can retain the data having eight levels, i.e., “111”, “110”, “101”, “100”, “011”, “010”, “001”, “000” in the ascending order of the threshold voltage. The determination of the higher-order bit is made in the first sense operation, the medium-order bit is made in the second sense operation, and the determination of the lower bit is made in a third sense operation. In the first sense operation, the first reference level is set to Vth3, and the determination whether the higher-order bit is the “0” data or the “1” data is made. In the second sense operation, the second reference level is set to Vth5 when the highest-order bit is the “0” data, and the second reference level is set to Vth1 when the highest-order bit is the “1” data. In the third sense operation, the third reference level is set to Vth6 when the highest-order bit and medium-order bit are the “0” data, and the third reference level is set to Vth4 when the highest-order bit is the “0” data while the medium-order bit is the “1” data. In the third sense operation, the third reference level is set to Vth0 when the highest-order bit and medium-order bit are the “1” data, and the third reference level is set to Vth2 when the highest-order bit is the “1” data while the medium-order bit is the “0” data.

The threshold voltage of the reference cell 31 is set to a value (near Vth3) located between the median of the threshold distribution of the memory cell MC retaining the “100” data and the median of the threshold distribution of the memory cell MC retaining the “011” data. In the case where the memory cell MC can retain the data with m (m is a natural number more than three) levels, the potential generated at the reference data line DLR when reading out the reference data is set to the value located between the median of the potential distribution generated at the data line DL in reading out the data (“100” in the case of the eight values) which is the (m/2)-th lowest from the data (“111” in the case of the eight values) having the lowest threshold voltage and the median of the potential distribution generated at the data line DL in reading out the data (“011” in the case of the eight values) which is the ((m/2)+1)-th lowest from the data (“111” in the case of the eight values) having the lowest threshold voltage.

In the embodiments, the NOR type flash memory has been described by way of example. For example, the embodiments can be applied to a NAND type flash memory, a 3Tr-NAND type flash memory in which the number of memory cell transistors is set to one in the configuration of the NAND type flash memory, and a 2Tr-flash memory in which the selection transistor on the bit line side is eliminated in the configuration of the 3Tr-NAND type flash memory.

Further, above embodiments are applied to a MONOS type flash memory. In the MONOS type flash memory, the memory cell has a stacked gate including a charge accumulation layer, a block layer and the control gate. The accumulation layer is formed on the gate insulating film. The charge accumulation layer is formed of an insulating film and holds the data. The block layer is formed on the charge accumulation layer. The block layer is formed of an insulating film with a dielectric constant higher than that of the charge accumulation layer. The control gate is formed on the block layer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a first memory cell which includes a MOS transistor and is capable of retaining n-bit (n is a natural number more than one) first data, the MOS transistor including a charge accumulation layer and a control gate;
a second memory cell which retains second data, the second data being a criterion for the first data; and
a sense amplifier which determines the first data read out from the first memory cell and amplifies the first data using a first reference level and a second reference level, the first reference level being obtained based on the second data read out from the second memory cell, the second reference level being generated based on the first reference level.

2. The device according to claim 1, wherein the sense amplifier determines whether one of the n bits of the first data is “0” or “1” based on the first reference level during a first sense operation, and
the sense amplifier determines whether one of the bits except for the bit determined during the first sense operation is “0” or “1” based on the second reference level during a second sense operation subsequent to the first sense operation, the second reference level being obtained by raising or lowering the first reference level according to determination result during the first sense operation.

3. The device according to claim 2, further comprising:
a first data line which connects the first memory cell and the sense amplifier to read out the first data; and
a second data line which connects the second memory cell and the sense amplifier to read out the second data,
wherein the first memory cell is capable of retaining the first data with m (m=2ⁿ) levels distinguished by a threshold voltage of the MOS transistor,
a potential generated at the second data line by reading out the second data is a value between a first potential and a second potential,
the first potential is generated at the first data line in reading out the first data having the (m/2)-th highest threshold voltage, and
the second potential is generated at the first data line in reading out the first data having the ((m/2)+1)-th highest threshold voltage.

4. The device according to claim 3, wherein, as a result of the first data readout, the second reference level is set higher than the first reference level when a potential at the first data line is higher than the first reference level, and
the second reference level is set lower than the first reference level when the potential at the first data line is lower than the first reference level.

5. The device according to claim 3, wherein the sense amplifier includes a latch type differential amplifier in which the first data is input to a first gate while the second data is input to a second gate, and
the second reference level is obtained by increasing or decreasing at least one of a first current path controlled by a potential at the first gate and a second current path controlled by a potential at the second gate during the second sense operation.

6. The device according to claim 3, wherein the sense amplifier includes a latch type differential amplifier in which the first data is input to a first gate while the second data is input to a second gate, and
the second reference level is obtained by increasing or decreasing at least one of an amount of current passed through a first current path controlled by a potential at the first gate and an amount of current passed through a second current path controlled by a potential at the second gate during the second sense operation.

7. The device according to claim 3, wherein the sense amplifier includes a current mirror type amplifier in which the first data is input to a first gate while the second data is input to a second gate, and
the second reference level is obtained by increasing or decreasing at least one of a first current path controlled by a potential at the first gate and a second current path controlled by a potential at the second gate during the second sense operation.

8. The device according to claim 3, wherein the sense amplifier includes a current mirror type amplifier in which the first data is input to a first gate while the second data is input to a second gate, and
the second reference level is obtained by increasing or decreasing at least one of an amount of current passed through a first current path controlled by a potential at the first gate and an amount of current passed through a second current path controlled by a potential at the second gate during the second sense operation.

9. The device according to claim 2, further comprising:
a first data line which connects the first memory cell and the sense amplifier to read out the first data; and
a second data line which connects the second memory cell and the sense amplifier to read out the second data,
wherein the first memory cell is capable of retaining the first data with m (m=2ⁿ) levels distinguished by a threshold voltage of the MOS transistor, and
a potential generated at the second data line by reading out the second data is a value within a distribution of a potential generated at the first data line in reading out the first data having any threshold voltage.

10. The device according to claim 9, wherein the sense amplifier includes a latch type differential amplifier in which the first data is input to a first gate while the second data is input to a second gate,
the number of first current paths controlled by a potential at the first gate is twice the number of second current paths controlled by a potential at the second gate during the first sense operation, and
the second reference level is obtained by increasing or decreasing at least one of the number of the first current paths and the number of the second current paths during the second sense operation.

11. The device according to claim 9, wherein the sense amplifier includes a latch type differential amplifier in which the first data is input to a first gate while the second data is input to a second gate,
an amount of current passed through a first current path controlled by a potential at the first gate is twice an amount of current passed through a second current path controlled by a potential at the second gate during the first sense operation, and
the second reference level is obtained by increasing or decreasing at least one of the amount of current passed through the first current path and the amount of current passed through the second current path during the second sense operation.

12. The device according to claim 9, wherein the sense amplifier includes a current mirror type amplifier in which the first data is input to a first gate while the second data is input to a second gate,
the number of first current paths controlled by a potential at the first gate is twice the number of second current paths controlled by a potential at the second gate during the first sense operation, and
the second reference level is obtained by increasing or decreasing at least one of the number of the first current paths and the number of the second current paths during the second sense operation.

13. The device according to claim 9, wherein the sense amplifier includes a current mirror type amplifier in which the first data is input to a first gate while the second data is input to a second gate,
an amount of current passed through a first current path controlled by a potential at the first gate is twice an amount of current passed through a second current path controlled by a potential at the second gate during the first sense operation, and
the second reference level is obtained by increasing or decreasing at least one of the amount of current passed through the first current path and the amount of current passed through the second current path during the second sense operation.

14. The device according to claim 2, wherein the sense amplifier determines the second reference level irrespective of the second data during the second sense operation.

15. A method for reading out data of a semiconductor memory device, comprising:
reading out n-bit (n is a natural number more than one) first data onto a first data line from a first memory cell;
reading out second data onto a second data line from a second memory cell, the second data being a criterion for the first data;
determining a first reference level based on the second data with a sense amplifier;
determining whether one of the n bits of the first data is “0” or “1” based on the first reference level;
determining a second reference level different from first reference level according to determination result based on the first reference level with the sense amplifier; and
determining whether one of the bits except for the bit determined based on the first reference level is “0” or “1” based on the second reference level.

16. The method according to claim 15, wherein, as a result of the first data readout, the second reference level is set higher than the first reference level when a potential at the first data line is higher than the first reference level, and
the second reference level is set lower than the first reference level when a potential at the first data line is lower than the first reference level.

17. The method according to claim 15, wherein the sense amplifier includes a latch type differential amplifier in which the first data is input to a first gate while the second data is input to a second gate, and
the second reference level is obtained by increasing or decreasing at least one of the number of current paths controlled by a potential at the first gate and the number of current paths controlled by a potential at the second gate.

18. The method according to claim 15, wherein the sense amplifier includes a latch type differential amplifier in which the first data is input to a first gate while the second data is input to a second gate, and
the second reference level is obtained by increasing or decreasing at least one of an amount of current passed through a current path controlled by a potential at the first gate and an amount of current passed through a current path controlled by a potential at the second gate.

19. The method according to claim 15, wherein the sense amplifier includes a current mirror type amplifier in which the first data is input to a first gate while the second data is input to a second gate, and
the second reference level is obtained by increasing or decreasing at least one of the number of current paths controlled by a potential at the first gate and the number of current paths controlled by a potential at the second gate.

20. The method according to claim 15, wherein the sense amplifier includes a current mirror type amplifier in which the first data is input to a first gate while the second data is input to a second gate, and
the second reference level is obtained by increasing or decreasing at least one of an amount of current passed through a current path controlled by a potential at the first gate and an amount of current passed through a current path controlled by a potential at the second gate.
